(19) United States
(12) Patent Application Publication
(10) Pub. No.: US 2015/0247241 A1
(43) Pub. Date: Sep. 3, 2015

(54) METHOD FOR PRODUCING GAS BARRIER FILM, GAS BARRIER FILM, AND ELECTRONIC DEVICE

(71) Applicant: KONICA MINOLTA, INC., Chiyoda-ku, Tokyo (JP)

(72) Inventor: Hidetoshi Ezure, Musashino-shi (JP)

(21) Appl. No.: 14/436,231

(22) PCT Filed: Oct. 11, 2013
(86) PCT No.: PCT/JP2013/077788

§ 371 Date: Apr. 16, 2015

(30) Foreign Application Priority Data
Oct. 19, 2012 (JP) 2012-231372

(51) Int. Cl. C23C 16/50; C23C 16/22; C23C 16/40; C23C 16/56

(52) U.S. Cl. CPC C23C 16/50; C23C 16/56; C23C 16/22; C23C 16/40

(57) ABSTRACT

A method for producing a gas barrier film with excellent gas barrier performance is maintained even in a high-temperature. The high-humidity usage environment properties and the flexibility (bendability) and adhesiveness are excellent. A gas barrier film, and an electronic device using the same is also disclosed.

### TECHNICAL FIELD

The present invention relates to a gas barrier film, a method for producing the gas barrier film, and an electronic device including the gas barrier film, and more specifically, to a gas barrier film usually included in an electronic device such as an organic electroluminescent (hereinafter abbreviated as “organic EL”) element, a method for producing the gas barrier film, and an electronic device including the gas barrier film.

### BACKGROUND ART

Gas barrier films composed of a laminate of a plurality of layers containing thin films of metal oxides such as aluminum oxide, magnesium oxide, and silicon oxide on plastic substrates or films have been widely used in packaging applications for articles which require shielding of various gases such as water vapor and oxygen for preventing deterioration of, for example, foods, industrial products, and pharmaceuticals.

In addition to packaging applications, gas barrier films are desired to be further applied to flexible electronic devices such as solar cell elements, organic electroluminescent (EL) elements, and liquid crystal display elements having flexibility, and considerable efforts have been made to achieve them. Unfortunately, these flexible electronic devices require significantly high gas barrier properties similar to those of glass substrates, and a gas barrier film having sufficient barrier properties has not yet been currently achieved.

Known examples of methods for forming such gas barrier films include vapor-phase epitaxial methods, such as chemical vapor deposition (plasma enhanced CVD methods), which oxidizes organosilicon compounds, such as tetraethoxysilane (hereinafter abbreviated as TEOS) in oxygen plasma under reduced pressure to form films on substrates, and physical vapor deposition (vacuum deposition or sputtering), which evaporates metallic silicon to deposit it on a substrate using a semiconductor laser in the presence of oxygen.

Patent literature 1 discloses a method for producing a gas barrier laminated film of 1×10⁻⁴ g/m²/day level in a roll-to-roll process using a plasma enhanced CVD apparatus as shown in FIG. 1 of the document. The gas barrier properties, adhesion, and flexibility of the gas barrier films produced by the method disclosed in Patent literature 1 are insufficient for use in electronic devices including organic EL devices in harsh environments of high temperature and high humidity, such as outdoor use, even though adhesion to substrates and flexibility are improved by the application of a plasma enhanced CVD method, which can increase the concentration carbon atom components near the substrate.

Patent literature 2 discloses a method for producing a gas barrier film having a gas barrier layer formed by a coating process, which exhibits superior performance in terms of productivity and cost. In the method disclosed in Patent literature 2, a film of polysilazane as an organic precursor compound produced on a side of the film by coating and drying is irradiated with vacuum ultraviolet light (also referred to as “VUV light”) to prepare a gas barrier layer. Patent literature 3 discloses a gas barrier film which has a gas barrier layer on one side and a conductive layer for imparting antistatic function on the opposite side of the film. However, Patent literature 2 and Patent literature 3 do not refer to any combination of the disclosed method thereof with the plasma enhanced CVD method and the effect obtained from the combination.

### PRIOR ART DOCUMENT

### Patent Literature

Patent Literature 1: WO2012/046767

Patent Literature 2: Japanese Unexamined Patent Application Publication No. 2011-143577

Patent Literature 3: Japanese Unexamined Patent Application Publication No. 2005-305801

### SUMMARY OF INVENTION

### Problems to be Solved by the Invention

An object of the present invention, which has been made to solve the above problems, is to provide a gas barrier film, which has gas barrier properties, high flexibility and sufficient adhesion required for use in electronic devices even in harsh environments of high temperature and high humidity such as outdoor use; a method for producing the gas barrier film; and an electronic device including the gas barrier film.

### Means for Solving the Problem

The inventors, who have conducted intensive studies, e.g., on the cause of the problems to solve the problems, have found that formation of a gas barrier layer containing carbon atoms, silicon atoms, and oxygen atoms as constituent elements formed on a first surface of a resin substrate using an oxygen gas and a material gas containing an organosilicon compound as deposition gas by plasma enhanced chemical vapor deposition in a discharge plasma space of an applied magnetic field between rollers; and formation of a conductive layer having a specific surface resistivity in a 23° C. and 50% RH environment on a second surface of the resin substrate opposite of the surface on which the gas barrier layer is formed can achieve a method for producing a gas barrier film which has superior gas barrier properties, high flexibility, and sufficient adhesion required for use in electronic devices even in harsh environments of high temperature and high humidity such as outdoor use, and have thus made the present invention.

The above problems addressed by the present invention are solved by the following aspects.

1. A method for producing a gas barrier film including a gas barrier layer containing carbon atoms, silicon atoms, and oxygen atoms on a first surface of a resin substrate, and a conductive layer on a second surface of the resin substrate opposite of the first surface of the resin surface on which the gas barrier layer is formed, the method including:

forming the gas barrier layer on the first surface of the resin substrate with an oxygen gas and a material gas containing an organosilicon compound by plasma enhanced chemical vapor deposition in a discharge space of an applied magnetic field between rollers; and

forming the conductive layer on the second surface of the resin substrate opposite of the first surface of the resin substrate on which the gas barrier layer is formed, the conductive layer having a specific surface resistivity ranging from 1×10³ to 1×10¹⁰ Ω/sq in an environment of 23° C. and 50% RH.

2. The method for producing a gas barrier film according to aspect 1, wherein the gas barrier layer is formed under the conditions satisfying all of following Items (1) to (4):

(1) the atomic percentage of carbon in the gas barrier layer continuously varies depending on a distance from the surface in a thickness direction within a region from a surface of the gas barrier layer to a distance of 89% of the thickness;

(2) the maximum value of the atomic percentage of carbon in the gas barrier layer is less than 20 at % in the thickness direction within the region from the surface of the gas barrier layer to a distance of 89% of the thickness;

(3) the atomic percentage of carbon in the gas barrier layer continuously increases across the thickness within a region from a distance of 90% to 95% of the thickness from the surface of the gas barrier layer (within a region of 5% to 10% from the surface adjacent to the resin substrate); and

(4) the maximum value of the atomic percentage of carbon in the gas barrier layer is at least 20 at % in the thickness direction within the region from a distance of 90% to 95% of the thickness from the surface of the gas barrier layer (within the region from 5% to 10% from the surface adjacent to the resin substrate).

3. The method for producing a gas barrier film according to aspect 1 or 2, wherein the conductive layer contains resin and metal oxide.

4. The method for producing a gas barrier film according to any one of aspects 1 to 3, wherein a polysilazane solution is applied on the gas barrier layer and dried to form a coated film, and the coated film is irradiated with vacuum ultraviolet light having a wavelength of 200 nm or less for modification to form a second gas barrier layer.

5. A gas barrier film including:

a gas barrier layer containing carbon atoms, silicon atoms, and oxygen atoms on a first surface of a resin substrate; and

a conductive layer on a second surface of the resin substrate opposite of the first surface of the resin substrate on which the gas barrier layer is formed,

wherein the gas barrier layer is formed on the first surface of the resin substrate with an oxygen gas and a material gas containing an organosilicon compound by plasma enhanced chemical vapor deposition in a discharge space of an applied magnetic field between rollers, and the conductive layer is formed on the second surface of the resin substrate opposite of the first surface of the resin substrate on which the gas barrier is formed, the conductive layer having a specific surface resistivity ranging from 1×10³ to 1×10¹⁰ Ω/sq in an environment of 23° C. and 50% RH.

6. A gas barrier film according to aspect 5, wherein the gas barrier film satisfies all of following Items (1) to (4):

(1) the atomic percentage of carbon in the gas barrier layer continuously varies depending on a distance from the surface in a thickness direction within a region from a surface of the gas barrier layer to a distance of 89% of the thickness;

(2) the maximum value of the atomic percentage of carbon in the gas barrier layer is less than 20 at % in the thickness direction within the region from the surface of the gas barrier layer to a distance of 89% of the thickness;

(3) the atomic percentage of carbon in the gas barrier layer continuously increases across the thickness within a region from a distance of 90% to 95% of the thickness from the surface of the gas barrier layer (within a region of 5% to 10% from the surface adjacent to the resin substrate); and

(4) the maximum value of the atomic percentage of carbon in the gas barrier layer is at least 20 at % in the thickness direction within the region from a distance of 90% to 95% of the thickness from the surface of the gas barrier layer (within the region from 5% to 10% from the surface adjacent to the resin substrate).

7. An electronic device including the gas barrier film according to aspects 5 or 6.

### Advantageous Effects of Invention

The aspects of the present invention provide a method of producing a gas barrier film, which has gas barrier properties, high flexibility, and sufficient adhesion required for use in electronic devices even in harsh environments of high temperature and high humidity such as outdoor use; and the gas barrier film.

The inventors, who have conducted intensive studies to solve the above problems, have found that the method for producing a gas barrier film having a gas barrier layer which is formed on a resin substrate with a specific surface resistivity, i.e., a resin substrate having a conductive layer with a specific surface resistivity in a range of 1×10³ to 1×10¹⁰ Ω/sq, by plasma enhanced chemical vapor deposition induced by discharge in an applied magnetic field between rollers can provide a gas barrier film which has excellent gas barrier properties, high flexibility, and sufficient adhesion required for use in electronic devices even in harsh environments of high temperature and high humidity such as outdoor use, and achieved the invention.

The mechanism on the advantageous effects achieved by such a configuration of the present invention has not yet been completely elucidated, but is speculated to be as follows.

As described above, a conductive layer, which is composed of metal oxide and resin and has a specific surface resistivity, is formed in advance on the second surface of the resin substrate, and then the gas barrier layer is formed on the first surface by plasma enhanced chemical vapor deposition induced by discharge in an applied magnetic field between rollers. It is presumed that this process can distribute more carbon atom components near the resin substrate, resulting in improved adhesion between the resin substrate and the gas barrier layer. Such tight adhesion enables the gas barrier film to have significantly high gas barrier properties and flexibility required for use in electronic devices even in harsh environments of high temperature and high humidity.

The mechanism of an improvement in adhesion, flexibility, and gas barrier properties by the configuration defined in the present invention is not clear yet. On adhesion, however, it is presumed that the specific range of conductivity of the resin substrate affects the magnetic field for plasma discharge generated between the rollers such that carbon atom components, which have a polarity relatively close to that of the resin substrate, are distributed predominantly in the resin substrate side of the gas barrier layer, resulting in the improved adhesion. On flexibility and gas barrier properties, it is presumed that the plasma discharge generated between rollers forms such a gas barrier layer that has a continuously changing concentration gradient of carbon atom components, resulting in the advantageous effects described above. Furthermore, presumably the combination effects of the distribution of carbon atom components near the resin substrate contributes to the effects exhibited even in harsh environments.

Incidentally, a plasma enhanced CVD using planar electrodes (horizontal transport) does not generate such a continuously changing concentration gradient of carbon atom components near the resin substrate. Accordingly, a tradeoff remains among adhesion, flexibility, and gas barrier properties; hence the CVD using planar electrodes described above can provide no solution. The advantageous effect of the invention is achieved if a continuously changing concentration gradient of carbon atom components is generated in a gas barrier layer formed by plasma enhanced chemical vapor deposition induced by discharge in an applied magnetic field between rollers and with this, the adhesion, flexibility, and gas barrier properties can be maintained.

Furthermore, polysilazane solution can be applied on the gas barrier layer to forma coated film, which is then irradiated with vacuum ultraviolet light (VUV) having a wavelength of 200 nm or less for modification to form a second gas barrier layer. It is presumed that minute defects remaining in the gas barrier layer can be filled with polysilazane gas barrier components from the top such that the gas barrier film can fully exhibit significantly high gas barrier properties required for use in electronic devices even in harsh environments of high temperature and high humidity, and flexibility.

### BRIEF DESCRIPTION OF DRAWINGS

FIG. 1 is a schematic cross-sectional view showing an exemplary basic configuration of a gas barrier film of the present invention.

FIG. 2 is a schematic diagram of an exemplary method for producing a gas barrier film using a plasma enhanced CVD apparatus involving plasma discharge in an applied magnetic field between rollers according to the present invention.

FIG. 3 is a graph showing exemplary silicon distribution, oxygen distribution, and carbon distribution curves in a gas barrier layer in the present invention.

FIG. 4 is a graph showing exemplary silicon distribution, oxygen distribution, and carbon distribution curves in a gas barrier layer in a comparative example.

FIG. 5 is a schematic diagram of an electronic device including a gas barrier film.

### EMBODIMENT FOR CARRYING OUT THE INVENTION

A method for producing a gas barrier film including a gas barrier layer containing carbon atoms, silicon atoms, and oxygen atoms on a first surface of a resin substrate; and a conductive layer on a second surface of the resin substrate opposite of the surface on which the gas barrier layer is formed, wherein the gas barrier layer is formed on the first surface with an oxygen gas and a material gas containing an organosilicon by plasma enhanced chemical vapor deposition in a discharge space of an applied magnetic field between rollers, and the conductive layer is formed on the second surface, the conductive layer having a specific surface resistivity ranging from 1×10³ to 1×10¹⁰ Ω/sq in an environment of 23° C. and 50% RH. These characteristics are common to the invention according to Aspects 1 to 7.

In a preferred embodiment of the present invention, a gas barrier film having further improved flexibility and adhesion is achieved by the following conditions: (1) The atomic percentage of carbon in the gas barrier layer continuously varies along a distance from a surface across a thickness within a region from the surface of the gas barrier layer to a distance of 89% of the thickness; (2) The maximum value of the atomic percentage of carbon in the gas barrier layer is less than 20 at % across the thickness within the region from the surface of the gas barrier layer to a distance of 89% of the thickness; (3) The atomic percentage of carbon in the gas barrier layer continuously increases across the thickness within a region from a distance of 90% to 95% of the thickness from the surface of the gas barrier layer (within a region of 5% to 10% of the thickness from the surface adjacent to the resin substrate); and (4) The maximum value of the atomic percentage of carbon in the gas barrier layer is at least 20 at % within the region from a distance of 90% to 95% of the thickness from the surface of the gas barrier layer (within the region from 5% to 10% of the thickness from the surface adjacent to the resin substrate). It is preferred that the conductive layer contains resin and metal oxide which can cause the carbon content to be highly controlled under predetermined conditions.

Preferably, polysilazane solution should be applied on the gas barrier layer into a coated film, which is then dried and irradiated with vacuum ultraviolet light having a wavelength of 200 nm or less for modification into a second gas barrier layer. The microdefects formed on the gas barrier layer during the CVD can be filled with polysilazane gas barrier components from the top, and thus significantly high gas barrier is achieved. Thus, it is preferred to provide an electronic device with a gas barrier film of the present invention. Such an electronic device can have excellent gas barrier properties, high flexibility, and sufficient adhesion even in environments of high temperature and high humidity such as outdoor use.

The term “gas barrier properties” herein represents a water vapor permeability of 3×10⁻³ g/m²·24 h or less determined under the conditions (temperature: 60±0.5° C., relative humidity (RH): 90±2%) in accordance with JIS K 7129-1992, and an oxygen permeability of 1×10⁻³ ml/m²·24 h·atm or less determined in accordance with JIS K 7126-1987.

As used herein, the term “vacuum ultraviolet irradiation”, “vacuum ultraviolet light”, “VUV”, or “VUV light” refers to light having a wavelength of 100 to 200 nm.

Components and embodiments of the present invention will now be described in detail. Throughout the specification, the term “to” indicating the numerical range is meant to be inclusive of the boundary values.

<<Gas Barrier Film>>

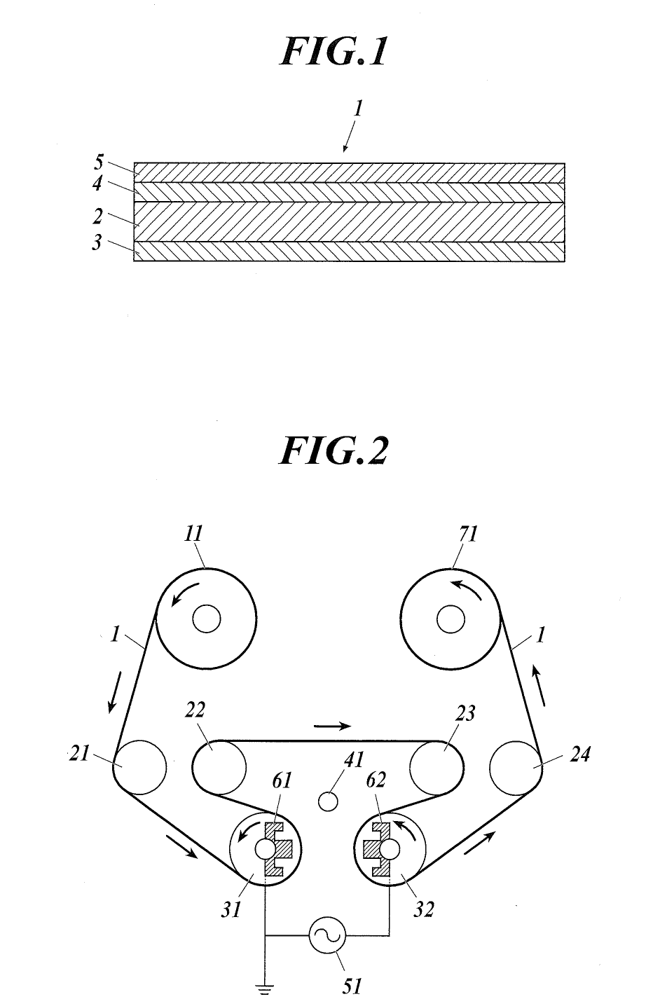

FIG. 1 is a schematic cross-sectional view illustrating an exemplary basic configuration of a gas barrier film of the present invention.

As shown in FIG. 1, a gas barrier film 1 of the present invention is provided with a resin substrate 2 which is a supporting body, a conductive layer 3 on a first surface of the resin substrate 2; a gas barrier layer 4 formed on a second surface of the resin substrate 2, which is opposite of the surface on which the conductive layer 3 is formed, through plasma enhanced chemical vapor deposition induced by discharge between rollers; and an optional second gas barrier layer 5 composed of a polysilazane-coated film treated with vacuum ultraviolet irradiation (VUV) formed on the gas barrier layer.

[1] Resin Substrate

The gas barrier film according to the present invention may be provided with any resin substrate composed of organic material that can support the gas barrier layer with gas barrier properties.

Examples of the material for the resin substrate of the invention include films of resins, such as methacrylic esters, poly(ethylene terephthalate) (PET), poly(ethylene naphthalate) (PEN), polycarbonates (PC), polyarylates, polystyrene (PS), aromatic polyamides, polyether-ether-ketones, polysulfones, polyethersulfones, polyimides, and polyetherimides; and films composed of two or more layers of the resins listed above. Poly(ethylene terephthalate) (PET), poly(ethylene naphthalate) (PEN), and polycarbonates (PC) are preferred from the viewpoint of cost and availability.

The thickness of the resin substrate is preferably within the range of 5 to 500 μm, or more preferably 25 to 250 μm.

The resin substrate according to the present invention is preferably transparent. A transparent gas barrier film can be produced by disposing a transparent layer on a transparent resin substrate. This can be used as a transparent substrate for electronic devices (e.g., organic EL devices).

The resin substrate composed of the resins listed above may be an unstretched or stretched film. A stretched film is preferred for high strength and low thermal expansion. Furthermore, phase differences can be adjusted through stretching.

The resin substrate according to the present invention can be produced through any known film production method. For example, an unstretched resin substrate that is substantially amorphous and non-oriented can be produced by melting a material resin in an extruder, extruding the melted resin through a circular or T die, and quenching the resin. Alternatively, an unstretched resin substrate that is substantially amorphous and non-oriented can be produced by melting the material resin in an organic solvent, casting and drying the molten resin on an endless metal or resin support, and separating the dried resin film from the support.

A stretched substrate can be produced by stretching the unstretched resin substrate through a known process, such as uniaxial stretching, successive biaxial stretching with a tenter, simultaneous biaxial stretching with a tenter, or simultaneous biaxial stretching of tubular film, in the direction of the flow (longitudinal axis (MD)) of the resin substrate and/or a width direction orthogonal to the flow of the resin substrate (lateral axis (TD)). In such a case, an appropriate stretching ratio can be selected in accordance with the constituent resin of the resin substrate. The stretching ratio in the longitudinal and lateral directions (MD and TD) is preferably within the range of 2 to 10 times.

The resin substrate according to the present invention may be subjected to relaxation processing and offline thermal processing for dimensional stability. The relaxation processing is preferably conducted after thermosetting during a stretching step in the film production process and before reeling the polyester film in or downstream of a tenter for lateral stretching of the polyester film. The relaxation process is preferably carried out in a range of 80° C. to 200° C., more specifically, in the range of 100° C. to 180° C. Any scheme of offline thermal processing may be employed. Examples of conveying schemes of the film include conveying by a group of rollers, conveying by blowing air against the film and lifting the film (blowing heated air on to one or both sides of the film through multiple slits), conveying through the use of heat radiating from an infrared heater, conveying downward by the weight of the film, and reeling the film at a low position. Lowering the conveying tension applied during thermal processing as much as possible promotes thermal contraction, which provides a resin substrate having high dimensional stability. The processing temperature is preferably within the range of Tg+50° C. to Tg+150° C., where Tg is the glass-transition temperature of the resin substrate.

An undercoat layer can be produced by applying an undercoating solution to one or both sides of the resin substrate according to the present invention as an inline process during the film production. The undercoating provided during the film production according to the present invention is referred to as inline undercoating. Any of the following resins can be preferably used for the preparation of an undercoating solution suitable for the present invention: polyester resins, acrylic modified polyester resins, polyurethane resins, acrylic resins, vinyl resins, vinylidene chloride resins, polyethylenimine vinylidene resins, polyethylenimine resins, polyvinyl alcohol resins, modified polyvinyl alcohol resins, or gelatin. A known additive may be added to the undercoating solution. The undercoating solution can be applied through a known wet-coating scheme, such as roller coating, gravure coating, knife coating, dip coating, or spray coating. The preferred quantity of the undercoating solution is approximately 0.01 to 2 g/m² (in a dry state).

[2] Conductive Layer

A gas barrier film of the present invention includes a resin substrate, a gas barrier layer according to the present invention on one surface (first surface) of the resin substrate and a conductive layer on the opposite surface (second surface) of the resin substrate, and the conductive layer has a specific surface resistivity ranging from 1×10³ to 1×10¹⁰ Ω/sq, more preferably ranging from 1×10⁸ to 1×10¹⁰ Ω/sq in an environment of 23° C. and 50% RH. A specific surface resistivity of not less than 1×10³ Ω/sq of the conductive layer allows for stabilized plasma discharge during formation of a gas barrier layer between rollers in plasma enhanced CVD, leading to the formation of a homogeneous gas barrier layer, whereas a specific surface resistivity of not more than 1×10¹⁰ Ω/sq of the conductive layer leads to the formation of a gas barrier layer having a desired element profile due to decreased conductivity.

The conductive layer having the specific surface resistivity specified above is disposed on the second surface of the resin substrate, and then the gas barrier layer is formed on the first surface through plasma enhanced chemical vapor deposition induced by discharge between rollers. This process can distribute many carbon atom components near the resin substrate, resulting in improved adhesion between the resin substrate and the gas barrier layer and improved gas barrier properties.

A specific surface resistivity of not less than 1×10³ Ω/sq of the conductive layer, which thus has sufficient conductivity, allows for stabilized plasma discharge during formation of a gas barrier layer by plasma enhanced CVD between rollers, which enables the control of the carbon atom components near the resin substrate under defined conditions, resulting in excellent adhesion and barrier properties, while a specific surface resistivity of not more than 1×10¹⁰ Ω/sq also enables the control of the amount of the carbon atom components near the resin substrate to a specific value, resulting in an improvement in adhesion and barrier properties.

The specific surface resistivity in the present invention is measured at an applied voltage of 100V at 23° C. and 50% RH with a digital ultra-high electrical resistance meter (R8340A) available from Advantest Co.

The conductive layer according to the present invention having specific surface resistivity within the above-described range may have any structure but preferably has a structure containing resin and metal oxide. It is preferred that the specific surface resistivity of the conductive layer be controlled by adequate adjustment of the ratio of the resin to the metal oxide and/or the conductivity of each constituent materials. The gas barrier film of the present invention, which is produced by plasma enhanced chemical vapor deposition under vacuum, should preferably contain metal oxide having humidity-independent conductivity to exhibit stable conductivity under vacuum.

(2.1) Resin

Examples of resins usable for the conductive layer according to the present invention include epoxy resins, acrylic resins, urethane resins, polyester resins, silicone resins, ethylene vinyl acetate (abbreviation: EVA) resins and the like. Resin compositions including these resins have significantly high transparency. Among the resin group, preferred are photocurable or thermosetting resins, particularly preferred are ultraviolet-curable resins in terms of productivity and film hardness, smoothness, and transparency of the formed conductive layer.

Any ultraviolet-curable resins that can be cured by ultraviolet irradiation to form a transparent resin can be used without any limitations. Acrylic resins, urethane resins, and polyester resins are particularly preferred in terms of film hardness, smoothness, and transparency of the formed conductive layer.

Examples of the acrylic resin composition include solutions of acrylate compounds having radical reactive unsaturated bonds, mercapto compounds having acrylate compounds and thiol groups, and polyfunctional acrylate monomers, such as epoxy acrylates, urethane acrylates, polyester acrylates, polyether acrylates, polyethylene glycol acrylates, and glycerol methacrylates. These resin compositions may also be used in combination in any proportion. Any resin including a reactive monomer that has one or more photopolymerizable unsaturated bonds in the molecule can be used without limitation.

One or more known photopolymerization initiators can be used alone or in combination.

(2.2) Metal Oxide

Metal oxides used for the formation of the conductive layer according to the present invention should have conductivity. Examples of the metal oxide include indium tin oxide (ITO), fluorine-doped tin oxide (FTO), tin oxide, indium zinc oxide (IZO), zinc oxide (ZnO), aluminum-doped zinc oxide (AZO), and gallium-doped zinc oxide (GZO).

From the viewpoint of transparency, coloration, and scattering for use in an electronic device, these metal oxides preferably are in particulate form with an average particle size in the range of preferably 1 to 300 nm, more preferably 5 to 100 nm, and most preferably 10 to 80 nm. Metal oxides having an average particle size of 1 nm or more allow for stable and ready production of conductive oxide particle dispersion liquid and coating solution for a transparent conductive film and can control the specific surface resistivity of the conductive layer within a desired range. Metal oxides having an average particle size of 300 nm or less can stably disperse in conductive oxide particle dispersion liquid and coating solution for a transparent conductive film, does not precipitate, and can achieve both the transmittance and specific surface resistivity desired.

The fine metal oxide particles used in the present invention are mixed with resin by any known process. Typically, the resin is dissolved in a solution, and then metal oxide particles are mixed with stirring using an agitator. Dispersants and other additives that may be added during stirring can be added before, after or simultaneously with the addition of the fine metal oxide particles, according to the demand. Organic solvents can be appropriately added if the resin binder is highly viscous or solid. If the dispersion cannot be readily achieved, fine metal oxide particles, a resin binder, and a solvent are added and then the system is uniformly mixed with high shear forces, using a mixer such as a Henschel mixer or Super mixer.

The metal oxide may be added in any content to the total mass of the conductive layer according to the present invention within a range that can achieve the specific surface resistivity described above. The content of the metal oxide to the total mass of the conductive layer is preferably 3 to 80 vol %, and particularly preferably 5 to 50 vol % from the viewpoint of the dispersion of metal oxide particles, the transparency and strength of the resin film.

(2.3) Method for Forming a Conductive Layer

The conductive layer according to the present invention can be formed as follows: the composition including the resin and metal oxide described above (coating solution for conductive layer) is applied by a wet process such as doctor blading, spin coating, dipping, table coating, spray coating, applicator coating, curtain coating, die coating, inkjet coating, and dispenser coating; and the resultant resin composition layer (if necessary, a curing agent is added) is cured by heat or UV to form a conductive layer.

Methods for curing ultraviolet-curable resins involve irradiation with UV rays having a wavelength in the range of 100 to 400 nm, preferably 200 to 400 nm emitted from an ultraviolet irradiation source, for example, an ultra-high pressure mercury lamp, a high-pressure mercury lamp, a low pressure mercury lamp, a carbon arc lamp, or a metal halide lamp or irradiation with electron beams in the wavelength region of 100 nm or less emitted from a scanning or curtain electron beam accelerator.

The conductive layer according to the present invention can have any thickness without particular restrictions, but has a thickness preferably in the range of 0.1 to 10 μm, particularly preferably in the range of 0.5 to 5 μm. The conductive layer may be composed of two or more layers.

The conductive layer according to the present invention can contain optional additives, such as antioxidants, plasticizers, matting agents, and thermoplastic resins. When the conductive layer is formed, any known organic solvent can be appropriately used for the conductive-layer coating solution including resins dissolved or dispersed in solvents.

(2.4) Surface Roughness (Ra) of Conductive Layer

The conductive layer according to the present invention has a surface roughness (Ra) in the range of preferably 0.3 to 5.0 nm, more preferably 0.5 to 3.0 nm.

A surface roughness of not less than 0.3 nm is appropriate for the conductive layer and stabilizes transportation of the film by rollers during formation of a gas barrier layer, resulting in accurate formation of the gas barrier layer by CVD. A surface roughness of not more than 5.0 nm facilitates appropriate transportation of the film which can come into close contact with rollers, resulting in formation of a gas barrier layer having desired gas barrier properties and adhesion with no effect on the discharge.

The surface roughness (Ra) of the conductive layer according to the present invention can be measured by the following procedure.

<Measurement of Surface Roughness; AFM Measurement>

The surface roughness (Ra) can be determined with an atomic force microscope (AFM), for example, DI3100 manufactured by Digital Instrument, Co. The roughness is calculated from a cross-sectional profile on the irregularity obtained by continuous measurement with a detector having a probe having a very small tip radius. A section of several tens of μm in a measurement direction is measured many times with the probe. The determined value is a roughness concerning the minute amplitude of irregularity.

[3] Gas Barrier Layer

A gas barrier layer according to the present invention is formed on the surface of a resin substrate with a deposition gas composed of oxygen gas and a material gas containing an organosilicon compound by plasma enhanced chemical vapor deposition in a discharge space of an applied magnetic field between rollers. The gas barrier layer is composed of carbon atoms, silicon atoms, and oxygen atoms as constituent elements.

Specifically, a resin substrate is wound through a pair of deposition rollers (roller electrodes) between which the film-forming gas is supplied during plasma discharge (plasma enhanced chemical vapor deposition) to form the gas barrier layer on the opposite surface, remote from the conductive layer, of the resin substrate.

In a more preferred embodiment, a gas barrier layer according to the present invention, which is formed using deposition gas composed of oxygen gas and a material gas containing an organosilicon compound contains carbon, silicon, and oxygen as constituent elements, further satisfies all the conditions on the carbon atom distribution profile defined by Items (1) to (4) below.

(1) The atomic percentage of carbon in the gas barrier layer continuously varies along the distance from the surface across the thickness within a region from the surface of the gas barrier layer to a distance of 89% of the thickness.

(2) The maximum value of the atomic percentage of carbon in the gas barrier layer is less than 20 at % across the thickness within the region from the surface of the gas barrier layer to a distance of 89% of the thickness.

(3) The atomic percentage of carbon in the gas barrier layer continuously increases across the thickness within a region from a distance of 90% to 95% of the thickness from the surface of the gas barrier layer (within a region of 5% to 10% of the thickness from the surface adjacent to the resin substrate).

(4) The maximum value of the atomic percentage of carbon in the gas barrier layer is at least 20 at % within the region from a distance of 90% to 95% of the thickness from the surface of the gas barrier layer (within the region from 5% to 10% of the thickness from the surface adjacent to the resin substrate).

In the present invention, the average percentage of the content of carbon atoms in the gas barrier layer according to the present invention can be determined by measurement of an XPS depth profile described below.

The gas barrier layer according to the present invention will now be described in detail below.

(3.1) Carbon Elemental Profile in Gas Barrier Layer

The gas barrier layer according to the present invention contains carbon atoms, silicon atoms, and oxygen atoms as constituent elements; and has a carbon atom content profile in a carbon distribution curve showing a relationship between distances across the thickness from the surface of the barrier layer and a ratio of the amount of carbon atoms to the total amount of silicon atoms, oxygen atoms, and carbon atoms (atomic percentage of carbon), wherein the carbon atom content profile satisfies all Items (1) to (4), resulting in a gas barrier film having improved flexibility and adhesion.

Furthermore, in a preferred embodiment, the gas barrier layer has a configuration in which the atomic percentage of carbon has a continuously varying concentration gradient in a specific region from the viewpoint of gas barrier properties and flexibility.

In the gas barrier layer according to the present invention with the carbon atom distribution profile, the carbon distribution curve in the layer has preferably at least one extreme value, more preferably at least two extreme values, most preferably three extreme values. A gas barrier film having no extreme values in the carbon distribution curve has insufficient gas barrier properties when it is bent. A gas barrier film having two or three extreme values in the carbon distribution curve has an absolute value of a difference in distance from the surface of the barrier layer across the thickness between neighboring extreme values in the carbon distribution curve of preferably 200 nm or less, more preferably 100 nm or less.

The extreme value in the present invention refers to the local maximum value or the local minimum value of an atomic percentage of each element.

(3.1.1) Local Maximum Value and Local Minimum Value

The local maximum value as used herein represents a point at which the atomic percentage of the element changes from an increase to a decrease versus the distance from the surface of the gas barrier layer, and at which the value of the atomic ratio of the element is at least 3 at % higher than that at another point further 20 nm distant from the surface of the gas barrier layer across the thickness.

The local minimum value as used herein represents a point at which the atomic percentage changes from a decrease to an increase versus the distance from the surface of the gas barrier layer and at which the value of the atomic ratio of the element is at least 3 at % lower than that at another point 20 nm distant from the surface of the gas barrier layer across the thickness.

In a preferred embodiment of the gas barrier layer according to the present invention, the maximum value of the atomic percentage of carbon is less than 20 at % within a region to 89% in a perpendicular direction from the surface (opposite the surface adjacent to the resin substrate), as defined in Item (2) according to the present invention, and the maximum value of the atomic percentage of carbon is at least 20 at % within a region of 90% to 95% in a perpendicular direction from the surface (within a region in a perpendicular direction from 5% to 10% of the thickness adjacent to the resin substrate), as defined in Item (4) according to the present invention. As defined above, the atomic percentage of carbon of 20 at % can be achieved by selecting carbon-rich compounds as the material gas.

(3.1.2) Continuous Changes in Concentration Gradient

In a preferred embodiment of the gas barrier layer according to the present invention, the atomic percentage of carbon in the gas barrier layer has a concentration gradient, and continuously varies within the region from the surface to 89% in the perpendicular direction, as defined in Item (1), and the atomic percentage of carbon continuously increases within a region of 90% to 95% from the surface in the perpendicular direction, that is, within a region from 5% to 10% across the thickness from the surface adjacent to the resin substrate to the other surface, as defined in Item (3).

The phrase “the concentration gradient of the atomic percentage of carbon continuously changes” as used herein indicates that the carbon distribution curve does not include a part in which the atomic percentage of carbon in the profile changes discontinuously. Specifically, this denotes that the relationship between the distance (x, unit: nm) from the surface of the gas barrier layer according to the present invention across the thickness of the layer calculated from an etching speed and etching time and the atomic percentage of carbon (C, unit: at %) satisfies following formula (F1):

(dC/dx)≦0.5 Formula (F1)

(3.2) Element Profiles in Gas Barrier Layer

The gas barrier layer according to the present invention contains carbon atoms, silicon atoms, and oxygen atoms as constituent elements. The preferable embodiments of atomic percentages and maximum and minimum values of each atom are described below.

<3.2.1> Relationship Between Maximum and Minimum Values of Atomic Percentage of Carbon

A gas barrier layer of the invention preferably has: an absolute value of the difference between the maximum and minimum values of the atomic percentage of carbon in the carbon distribution curve is 5 at % or more, more preferably 6 at % or more, most preferably 7 at %. The absolute value of the difference between the maximum and minimum values of the atomic percentage of carbon of 5 at % or more prevents cracks in the gas barrier film due to bending the gas barrier film formed and leads to satisfactory bending resistance of the film.

<3.2.2> Relationship Between Maximum Value and Minimum Value of Atomic Percentage of Oxygen

According to the present invention, the absolute value of the difference between the maximum value and the minimum value on the oxygen distribution curve of the gas barrier layer is preferably 5 at % or more, more preferably 6 at % or more, most preferably 7 at % or more. Such an absolute value of 5 at % or more prevents cracks in the gas barrier film due to bending the obtained gas barrier film and leads to satisfactory bending resistance of the film.

<3.2.3> Relationship Between Maximum Value and Minimum Value of Atomic Percentage of Silicon

According to the present invention, the absolute value of the difference between the maximum value and the minimum value on the silicon distribution curve of the gas barrier layer is preferably less than 5 at %, more preferably less than 4 at %, most preferably less than 3 at %. An absolute difference of less than 5 at % provides a gas barrier film having a mechanical strength and satisfactory gas barrier properties.

<3.2.4> Atomic Percentage of a Total of Oxygen and Carbon Atoms

In the gas barrier layer according to the present invention, in a distribution curve of a total of oxygen and carbon atoms (also referred to oxygen-carbon distribution curve) showing a relationship between the distance from the surface of the gas barrier layer across the thickness and the percentage of the total amount of oxygen atoms and carbon atoms (total atomic percentage of oxygen and carbon) relative to the total amount of silicon atoms, oxygen atoms and carbon atoms, the absolute value of the difference between the maximum and minimum values of total atomic percentage of oxygen and carbon is preferably less than 5 at %, more preferably less than 4 at %, especially preferably less than 3 at %. The gas barrier film having an absolute value of less than 5 at % can achieve sufficient gas barrier properties.

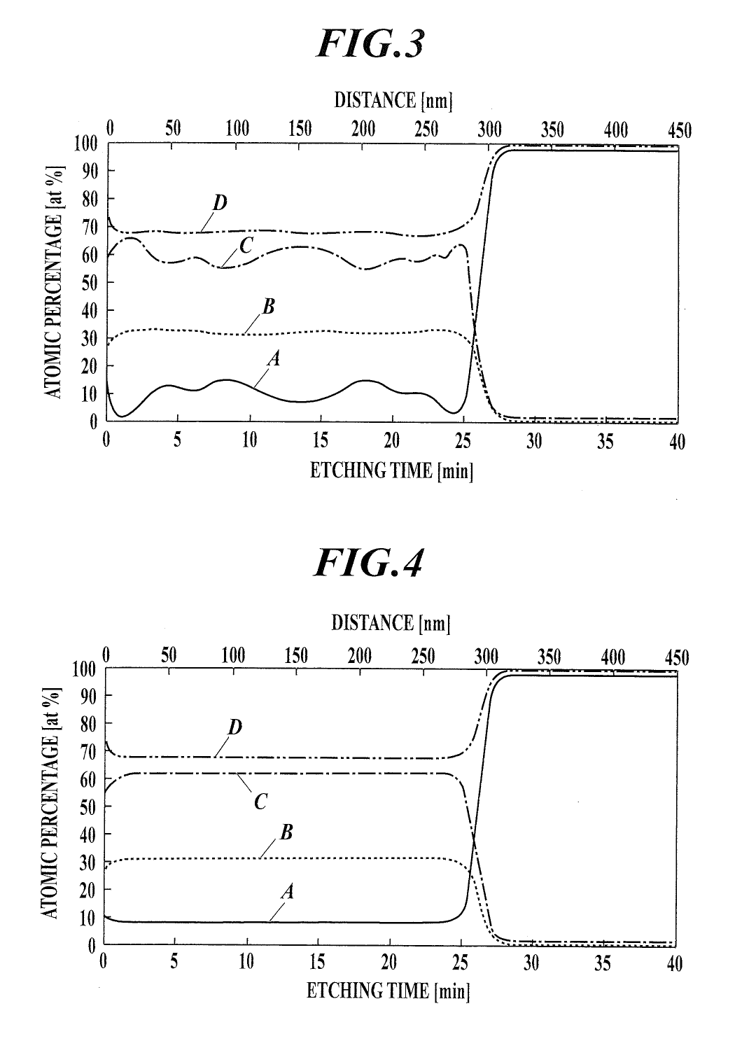

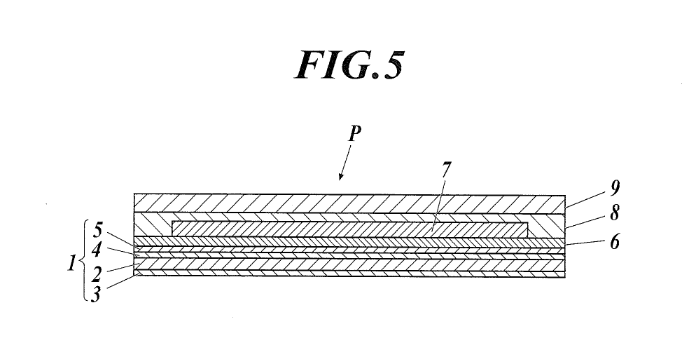

In the above description of such a carbon atom distribution profile (silicon distribution curve, oxygen distribution curve, and carbon distribution curve) as shown in FIGS. 3 and 4, “the total amount of silicon atoms, oxygen atoms and carbon atoms” refers to the number of total atoms of silicon atoms, oxygen atoms, and carbon atoms (atom number), and “the amount of carbon atoms” refers to the number of carbon atoms. The term “at %” as herein refers to an atomic percentage (atomic %) relative to the number of total atoms of silicon, oxygen, and carbon which is taken as 100%. The same applies for “the amount of silicon atoms” and “the amount of oxygen atoms” in the silicon distribution curve, the oxygen distribution curve and, the oxygen-carbon distribution curve as shown in FIGS. 3 and 4.

(3.3) XPS Depth Profiling

The distribution curves of silicon, oxygen, carbon, and the sum of oxygen and carbon contents across the thickness of the gas barrier layer can be prepared through XPS depth profiling in which the interior of the specimen is exposed in sequence for analysis of the surface composition through a combination X-ray photoelectron spectroscopy (XPS) and ion-beam sputtering using a rare gas, such as argon.

The distribution curve acquired through such XPS depth profiling has, for example, a vertical axis representing the atomic ratio (at %) of the elements and a horizontal axis representing the etching time (sputtering time). With a distribution curve of an element versus the etching time (horizontal axis), the etching time correlates significantly with the distance from the surface of the gas barrier layer along the thickness of the gas barrier layer. Thus, “the distance from the surface of the gas barrier layer across the thickness of the gas barrier layer” can be the distance from the surface of the gas barrier layer calculated on the basis of the relationship between the etching rate and etching time used in the XPS depth profiling. For the XPS depth profiling, it is preferred to select ion-beam sputtering of rare gas using argon (Ar⁺) as the ionic species and an etching rate of 0.05 nm/sec (equivalent to a thermally-oxidized SiO2 film).

According to the present invention, for the formation of a gas barrier layer having a uniform surface and excellent gas barrier properties, it is preferred that the gas barrier layer be substantially uniform in the direction of the film surface (the direction parallel to the surface of the gas barrier layer). In the present invention, a gas barrier layer being substantially uniform in the direction of the film surface has distribution curves of oxygen, carbon, and the sum of oxygen and carbon contents at any two points on the surface of the gas barrier layer measured by XPS depth profiling in which the carbon distribution curves for the two points contain the same number of extreme values, and the absolute value of the difference between the maximum value and the minimum value of the atomic percentage of carbon of the carbon distribution profiles are identical or within 5 at % or less.

The gas barrier film according to the present invention should include at least one gas barrier layer that satisfies all of the conditions (1) to (4) described above and may include two or more gas barrier layers. If two or more gas barrier layers are provided, the gas barrier layers may be composed of an identical material or different materials. If two or more gas barrier layers are provided, the gas barrier layers may be disposed on one of the sides of the resin substrate or on both sides of the resin substrate. One or more of the gas barrier layers may be replaced with a layer or layers that do not have gas barrier properties.

If the silicon, oxygen, and carbon distribution curves respectively have atomic percentages of silicon, oxygen, and carbon that satisfy the condition represented by Expression (2) in an area corresponding to 90% or more of the thickness of the layer, the atomic percentage of silicon relative to the sum of silicon, oxygen, and carbon contents in the gas barrier layer is preferably within the range of 19 to 40 at %, more preferably 30 to 40 at %. The atomic percentage of oxygen relative to the sum of silicon, oxygen, and carbon contents in the gas barrier layer is preferably within the range of 33 to 67 at %, more preferably 41 to 62 at %. The atomic percentage of carbon relative to the sum of silicon, oxygen, and carbon contents in the gas barrier layer is preferably within the range of 1 to 19 at %, more preferably 3 to 19 at %.

(3.4) Thickness of Gas Barrier Layer

The thickness of the gas barrier layer of the invention is preferably within the range of 5 to 3000 nm, more preferably 10 to 2000 nm, more preferably 100 to 1000 nm. A gas barrier layer having a thickness within these ranges has excellent gas barrier properties, such as oxygen-gas and water-vapor barrier properties, and do not experience degradation of gas barrier properties after bending.

If the gas barrier film according to the present invention includes a plurality of gas barrier layers, the total thickness of the gas barrier layers is normally within the range of 10 to 10000 nm, preferably 10 to 5000 nm, more preferably 100 to 3000 nm, most preferably 200 to 2000 nm. Gas barrier layers having a total thickness within these ranges achieve sufficient gas barrier properties, such as oxygen-gas and water-vapor barrier properties, and are less susceptible to bending that could cause degradation of the gas barrier properties.

(3.5) Method of Producing Gas Barrier Layer

A gas barrier layer according to the present invention is formed on a resin substrate through plasma enhanced chemical vapor deposition in a magnetic field applied to the discharge space between rollers.

Specifically, the gas barrier layer of the invention formed through a plasma enhanced processing apparatus involving plasma discharge in an applied magnetic field between rollers is a film formed on a resin substrate through plasma enhanced chemical vapor deposition in which the resin substrate passes through a pair of deposition rollers and is exposed to plasma discharge while deposition gas is supplied between the deposition rollers. During discharge in the magnetic field between a pair of deposition rollers, it is preferred that the poles of the deposition rollers be alternately inverted. The deposition gas used in such plasma enhanced chemical vapor deposition preferably includes material gas including organosilicon compounds and oxygen gas. The content of the oxygen gas in the deposition gas to be supplied is preferably equal to or less than a theoretical quantity required for the complete oxidation of the entire quantity of the organosilicon in the deposition gas. The gas barrier layer in the gas barrier film according to the present invention is preferably formed through a continuous deposition process.

A method of producing the gas barrier film according to the present invention will now be described.

The gas barrier film of the present invention is produced by forming a gas barrier layer on the surface of a substrate (optionally, an interlayer can be disposed) in a plasma enhanced processing apparatus induced by discharge in an applied magnetic field between rollers.

The gas barrier layer according to the present invention is formed by plasma enhanced chemical vapor deposition induced by discharge in an applied magnetic field between rollers so that the atomic percentage of carbon has a concentration gradient which continuously varies in the layer.

In plasma enhanced chemical vapor deposition (plasma enhanced CVD) in a magnetic field applied to the discharge space between rollers according to the present invention, it is preferred to generate plasma through an electric discharge in the magnetic field applied to the space between the deposition rollers. In the present invention, a resin substrate passes through a pair of deposition rollers providing a magnetic field for generating plasma. The generation of plasma through an electric discharge in the space between the deposition rollers through which a resin substrate passes varies the distance between the resin substrate and each deposition roller. This can form a gas barrier layer having an atomic percentage of carbon that has a concentration gradient and a composition which continuously varies in the layer.

Simultaneous formation is achieved for a portion of the surface of the resin substrate on one of the deposition rollers during the formation of the gas barrier layer and another portion of the surface of the resin substrate on the other deposition roller. This achieves efficient formation of thin films, doubles the deposition rate, and provides films with an identical structure. Thus, the number of extreme values in the carbon distribution curves can at least be doubled, and gas barrier layers that satisfy all of the conditions (1) to (4) can be efficiently produced.

The gas barrier film according to the present invention includes a gas barrier layer formed on the surface of a substrate preferably through a roll-to-roll processing in view of productivity.

Although any apparatus can be used for the production of gas barrier films through plasma enhanced chemical vapor deposition, the apparatus preferably should include a plasma power source and at least a pair of deposition rollers provided with magnetic field applicators and be capable of discharging in the space between the deposition rollers. For example, the production apparatus illustrated in FIG. 2 can continuously produce gas barrier films through plasma enhanced chemical vapor deposition in a roll-to-roll process.

With reference to FIG. 2, a method of producing a gas barrier film of the present invention through plasma enhanced chemical vapor deposition will now be described in detail. FIG. 2 is a schematic view illustrating an example plasma CVD apparatus (producing plasma in the magnetic field between rollers) preferred for producing a gas barrier film according to the present invention. A resin substrate 1 described below has a conductive layer of the invention on the rear surface.

The plasma CVD apparatus in FIG. 2 mainly includes a delivery roller 11, conveyer rollers 21, 22, 23, and 24, deposition rollers 31 and 32, a deposition gas supply pipe 41, a power source 51 for plasma generation, magnetic-field generators 61 and 62 disposed inside the deposition rollers 31 and 32, and a reeling roller 71. Such a plasma CVD apparatus includes a vacuum chamber (not shown) that accommodates at least the deposition rollers 31 and 32, the deposition gas supply pipe 41, the power source 51 for plasma generation, and the magnetic-field generators 61 and 62. The vacuum chamber (not shown) of such a plasma CVD apparatus is connected to a vacuum pump (not shown). The vacuum pump can appropriately adjust the pressure in the vacuum chamber.

The deposition rollers of such a plasma CVD apparatus are connected to the power source 51 for plasma generation such that a pair of deposition rollers (deposition rollers 31 and 32) can function as opposing electrodes. The power source 51 supplies electric power to the pair of deposition rollers 31 and 32 for discharging in the space between the deposition rollers 31 and 32. This can generate plasma in the space (discharge space) between the deposition rollers 31 and 32. The deposition rollers 31 and 32, which are used as electrodes, may be composed of any material suitable for electrodes and designed as appropriate. The deposition rollers (deposition rollers 31 and 32) in such a plasma CVD apparatus are preferably disposed on a single plane such that the central axes are substantially parallel to the plane. Such arrangement of the deposition rollers (deposition rollers 31 and 32) can double the deposition rate and at least double the number of extreme values in the carbon distribution curves because films with an identical structure can be deposited.

The deposition rollers 31 and 32 accommodate the magnetic-field generators 61 and 62, respectively, which are fixed so as not to rotate even when the deposition rollers rotate.

The deposition rollers 31 and 32 may be any appropriate known roller. The deposition rollers 31 and 32 are preferred to have identical diameters for the efficient deposition of the films. The diameter of the deposition rollers 31 and 32 is preferably in the range of 300 to 1000 mmφ, more preferably 300 to 700 mmφ, in view of the discharge conditions and the space in the chamber. A diameter 300 mmφ or more is preferred because the plasma discharge space is large enough to maintain productivity, and the total heat from the plasma discharge is prevented from being applied to the film in a short time to minimize residual stress. A diameter 1000 mmφ or less is preferred for a practical design of the apparatus including uniformity of the plasma discharge space.

The delivery roller 11 and the conveyer rollers 21, 22, 23, and 24 of such a plasma CVD apparatus may be any appropriate known roller. The reeling roller 71 may be any appropriate known roller that can reel the resin substrate 1 including the gas barrier layer.

The deposition gas supply pipe 41 may be any appropriate pipe that can supply or discharge a material gas and oxygen gas at a predetermined rate. The power source 51 for plasma generation may be any appropriate power source for a known plasma generator. The power source 51 for plasma generation supplies power to the deposition rollers 31 and 32 connected thereto and can use the deposition rollers 31 and 32 as opposing electrodes for electrical discharge. The power source 51 for plasma generation is preferably a source (AC source, for example) that can alternatively invert the poles of the deposition rollers so as to efficiently perform plasma enhanced CVD. The power source 51 for plasma generation is preferred to apply power in the range of 100 W to 10 kW and have an AD frequency in the range of 50 Hz to 500 kHz so as to efficiently perform plasma enhanced CVD. The magnetic-field generators 61 and 62 may be any appropriate known magnetic-field generator.

The plasma CVD apparatus, such as that illustrated in FIG. 2, can produce the gas barrier film according to the present invention through appropriate adjustment of, for example, the type of material gas, the electric power of the electrode drum in the plasma generator, the intensity of the magnetic field generated by the magnetic-field generator, the pressure in the vacuum chamber, the diameter of the deposition rollers, and the conveying rate of the resin substrate. That is the plasma CVD apparatus illustrated in FIG. 2 supplies a deposition gas (for example, material gas) into the vacuum chamber and generates a plasma discharge between the deposition rollers (deposition rollers 31 and 32) during application of magnetic fields so as to breakdown the deposition gas (for example, material gas) by the plasma, and deposit the gas barrier layer of the invention on the surface of the resin substrates 1 on the deposition rollers 31 and 32 through plasma enhanced CVD. Through such deposition process, the resin substrates 1 are conveyed by the delivery roller 11, the deposition roller 31, and other rollers, and the gas barrier layer is formed on the surface of the resin substrates 1 through continuous roll-to-roll deposition.

<3.5.1> Material Gas

The material gas for the deposition gas for the formation of the gas barrier layer of the invention is composed of an organosilicon compound which contains at least silicon.

Examples of organosilicon compounds applicable to the present invention include hexamethyldisiloxane, 1,1,3,3-tetramethyldisiloxane, trimethyl(vinyl)silane, methyltrimethylsilane, hexamethyldisilane, methylsilane, dimethylsilane, trimethylsilane, diethylsilane, propylsilane, phenylsilane, vinyltriethoxysilane, vinyltrimethoxysilane, tetramethoxysilane, tetraethoxysilane, phenyltrimethoxysilane, methyltriethoxysilane, and octamethylcyclotetrasiloxane. Among these organosilicon compounds, hexamethyldisiloxane and 1,1,3,3-tetramethyldisiloxane are preferred in view of the handling during deposition and the gas barrier properties of the acquired gas barrier layer. These organosilicon compounds may be used alone or in combination.

The deposition gas contains gaseous oxygen as a reactive gas in addition to the material gas. Gaseous oxygen reacts with the material gas to form inorganic compounds, such as oxides.

The deposition gas may contain a carrier gas, if required, for the supplying of the material gas to the vacuum chamber. Alternatively, the deposition gas may contain a discharge gas, if required, for the generation of plasma discharge. Such carrier gas and discharge gas can be any appropriate known gas, including rare gases, such as helium, argon, neon, and xenon, and hydrogen gas.

Such a deposition gas containing a material gas containing an organosilicon compound including silicon and gaseous oxygen preferably include gaseous oxygen at a percentage not too higher than the theoretical percentage of gaseous oxygen required for complete reaction of the material gas and gaseous oxygen. If the percentage of gaseous oxygen is too high, the gas barrier layer according to the present invention cannot be readily acquired. A barrier film having predetermined properties can be acquired through the use of a deposition gas preferably having not more than a theoretical percentage of oxygen required for complete oxidation of the organosilicon compound in the deposition gas.

Hexamethyldisiloxane (organosilicon compound (HMDSO:(CH₃)₆Si₂O)), which is a typical example of the material gas, and oxygen (O₂), which is a typical example of the reactive gas, will now be described.

For the production of a silicon-oxygen thin film through a reaction of a deposition gas containing hexamethyldisiloxane (HMDSO:(CH₃)₆Si₂O) as a material gas and oxygen (O₂) as a reactive gas through plasma enhanced CVD, a thin film of silicon dioxide (SiO₂) is produced through the following reaction:

(CH₃)₆Si₂O+12O₂→6CO₂+9H₂O+2SiO₂ (1)

In such a reaction, 12 moles of oxygen is required for complete oxidation of 1 mole of hexamethyldisiloxane. Thus, the complete oxidation of a deposition gas containing 12 mole or more oxygen for each mole of hexamethyldisiloxane generates a uniform silicon dioxide layer. Thus, the ratio of gas flow rate of the material is adjusted to a ratio below the theoretical ratio for complete reaction so as to maintain an incomplete reaction. That is, the amount of oxygen must be set to less than 12 moles for each mole of hexamethyldisiloxane, which is lower than the stoichiometric ratio of oxygen.

In an actual reaction in the chamber of the plasma enhanced CVD apparatus, the hexamethyldisiloxane, which is the material gas, and the oxygen, which is the reactive gas, are supplied from the gas supply pipe to the deposition region. Thus, even if the quantity of the reactive oxygen gas in moles (flow rate) is 12 times of that of hexamethyldisiloxane, which is the material gas, the reaction actually cannot be completed. A complete reaction is presumed to be accomplished only when oxygen is supplied in a quantity that significantly exceeds the stoichiometric ratio. For example, the mole quantity (flow rate) of oxygen may be set to at least approximately 20 times that of hexamethyldisiloxane so as to produce silicon oxide through a complete reaction in CVD. Thus, the mole quantity (flow rate) of oxygen is preferably not more than 12 times, which is the stoichiometric ratio (more preferably not more than 10 times) that of the hexamethyldisiloxane, which is the material gas. With such contents of hexamethyldisiloxane and oxygen, the carbon atoms and hydrogen atoms in the hexamethyldisiloxane that are not completely oxidized are absorbed by the gas barrier layer. Thus, the desired gas barrier layer can be formed, and the acquired gas barrier film has excellent barrier properties and flexibility. If the mole quantity (flow rate) of oxygen is too small relative to the mole quantity (flow rate) of hexamethyldisiloxane in the deposition gas, the unoxidized carbon and hydrogen atoms are excessively absorbed by the gas barrier layer. Thus, the barrier film will have low transparency and cannot be used as flexible substrates for electronic devices, such as organic EL devices and organic thin-film photovoltaic cells, which require transparency.

In this view, the lower limit of the mole quantity (flow rate) of oxygen relative to the mole quantity (flow rate) of hexamethyldisiloxane in the deposition gas is preferably 0.1 times or more the mole quantity (flow rate) of hexamethyldisiloxane in the deposition gas, more preferably 0.5 times or more.

<3.5.2> Vacuum Level

The pressure (vacuum level) in the vacuum chamber can be appropriately adjusted depending on the type of material gas and is preferably in the range of 0.5 to 100 Pa.

<3.5.3> Roller Deposition

In such a plasma enhanced CVD using the plasma CVD apparatus in FIG. 2, the electrical power to be applied to electrode drums connected to the plasma power source 51 (which are disposed on the deposition rollers 31 and 32 in FIG. 2) for preparation of a discharge space between the deposition rollers 31 and 32 can be appropriately adjusted depending on the type of the material gas and the pressure in the vacuum chamber. Although the electrical power may vary, the preferred electrical power is in the range of 0.1 to 10 kW. Electrical power applied within such a range does not generate contaminative particles, and the heat generated during deposition is controllable. Thus, heat distortion, heat degradation, and wrinkles in the resin substrate due to the increase in temperature at the surface of the substrate during deposition do not occur. In addition, damage on deposition rollers can be prevented which is due to the melting of the resin substrate due to heat and the discharge of a large current between the bare deposition rollers.

The conveying rate (line rate) of the resin substrate 1 can be appropriately adjusted depending on the type of material gas and the pressure in the vacuum chamber and is preferably in the range of 0.25 to 100 m/min, more preferably 0.5 to 20 m/min. If the line rate is within these ranges, wrinkles in the resin substrate due to heat are not readily formed, and the thickness of the gas barrier layer to be deposited can be sufficiently controlled.

FIG. 3 is a graph showing exemplary profiles measured by XPS depth analysis of each element across the thickness of the gas barrier layer of the present invention formed as described above.

FIG. 3 illustrates exemplary silicon, oxygen, and carbon distribution curves in a gas barrier layer in the present invention.

FIG. 3 illustrates a carbon distribution curve A, silicon distribution curve B, oxygen distribution curve C, oxygen-carbon distribution curve D. FIG. 3 demonstrates that, in the configuration of the gas barrier layer according to the present invention, the maximum value of the atomic percentage of carbon in the gas barrier layer is less than 20 at % within the region from the surface of the gas barrier layer to 89% in a perpendicular direction; and the atomic percentage of carbon has a concentration gradient, and continuously varies within the region from the surface to 89% in the perpendicular direction (corresponding to Items (1) and (2) defined by the present invention).

The atomic percentage of carbon in the gas barrier continuously increases and has a maximum value of the atomic percentage of carbon of at least 20 at % within the region from 90% to 95% in a perpendicular direction from the surface (within the region from 5% to 10% in the perpendicular direction from the surface adjacent to the resin substrate) (corresponding to Items (3) and (4) defined by the present invention).

FIG. 4 is a graph showing exemplary carbon distribution curve A, silicon distribution curve B, and oxygen distribution curve C in a gas barrier layer in a comparative example.

FIG. 4 shows the carbon atom profile A, silicon atom profile B, and oxygen atom profile C in the gas barrier layer formed in a plasma enhanced CVD discharge apparatus including flat electrodes (horizontal transport) and demonstrates no continuous change in the concentration gradient of the carbon atom component A.

[4] Second Gas Barrier Layer

The gas barrier film of the invention preferably includes a second gas barrier layer on the above-described gas barrier layer of the invention. To form the second gas barrier layer, a solution containing polysilazane is applied on the gas barrier layer (a wet process) and then dried, and the resulting layer is irradiated with vacuum ultraviolet rays (VUV rays) having a wavelength of 200 nm or less for modification.

The second gas barrier layer provided on the gas barrier layer deposited through plasma CVD in a magnetic field applied to the discharge space between rollers according to the invention is preferred because minute defects remaining in the gas barrier layer can be covered from above with polysilazane components in the second gas barrier layer to efficiently prevent gas purge and enhance the gas barrier properties and flexibility.

The second gas barrier layer should preferably have a thickness in a range of 1.0 to 500 nm, more preferably 10 to 300 nm. A second gas barrier layer having a thickness of 1 nm or greater can exhibit desired gas barrier properties. A second gas barrier layer having a thickness of 500 nm or less can prevent defects, such as cracks, on a dense silicon oxynitride film.

<4.1> Polysilazane

The polysilazane according to the present invention is a polymer having a molecular structure of silicon-nitrogen bonds and is a precursor of silicon oxynitride. Any polysilazane may be used, and preferred is a compound having a structure represented by Formula (1):

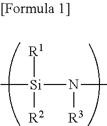

where R¹, R², and R³ represent hydrogen atoms, alkyl groups, alkenyl groups, cycloalkyl groups, aryl groups, alkylsilyl groups, alkylamino groups, or alkoxy groups.

In the present invention, the polysilazane should preferably be perhydropolysilazane (PHPS), wherein R¹, R², and R³ are hydrogen atoms, to provide a dense second gas barrier layer.

The perhydropolysilazane is in the form of liquid or solid, and presumably has straight-chain structures and cyclic structures that are composed mainly of six-membered rings and eight-membered rings, and a number average molecular weight (Mn) of approximately 600 to 2000 (polystyrene equivalent value by gel permeation chromatography).

The polysilazane is commercially available in the form of solution in organic solvent. The commercially available polysilazane can be directly used as a polysilazane solution. Examples of a commercially available polysilazane solution include NN120-20, NAX120-20, and NL120-20, which are available from AZ Electronic Materials.

A second gas barrier layer can be produced by applying the polysilazane solution to form a coating layer onto the first gas barrier layer, which is formed through plasma-enhanced CVD in a magnetic field applied to the discharge space between the rollers, drying the coating layer, and irradiating the coating layer with vacuum ultraviolet beams.

It is preferred that the polysilazane solution should contain any organic solvent other than alcohol solvent and aqueous solvent, which are readily reacted with the polysilazane. Examples of the usable organic solvent include hydrocarbon solvents, such as aliphatic hydrocarbons, alicyclic hydrocarbons, and aromatic hydrocarbons, halogenated hydrocarbon solvents, and ethers, such as aliphatic ethers and alicyclic ethers. Specific examples of the organic solvent include carbon hydrides, such as pentane, hexane, cyclohexane, toluene, xylene, solvesso, and turpentine, halogenated hydrocarbons, such as methylene chloride and trichloroethane, and ethers, such as dibutyl ether, dioxane, and tetrahydrofuran. Appropriate organic solvent may be selected from these examples depending on purposes, such as the solubility of the polysilazane and the evaporation rate of the organic solvent. These organic solvents may be used in combination.

The concentration of the polysilazane in the coating solution for the formation of the second gas barrier layer depends on the thickness of the second gas barrier layer or the pot life of the solution, and should preferably be in a range of 0.2 to 35 mass %.

To accelerate denaturation into silicon oxynitride, amine catalysts or metal catalysts, such as Pt compounds, for example, Pt acetylacetonate, Pd compounds, for example, Pd propionate, and Rh compounds, for example, Rh acetylacetonate may be applied to the coating solution for the formation of a second gas barrier layer. Particularly preferred are amine catalysts in the present invention. Specific examples of the amine catalysts include N,N-diethylethanolamine, N,N-dimethylethanolamine, triethanolamine, triethylamine, 3-morpholinopropylamine, N,N,N′,N′-tetramethyl-1,3-diaminopropane, and N,N,N′,N′-tetramethyl-1,6-diaminohexane.

The amount of the catalyst to the polysilazane should preferably be in a range of 0.1 to 10 mass % relative to the total mass of the coating solution for the formation of an second gas barrier layer, more preferably 0.2 to 5 mass %, still more preferably 0.5 to 2 mass %. The polysilazane solution containing the catalyst within the range can prevent an excessive formation of silanol compounds, decrease in film density, and increase in film defect that are caused by a rapid reaction.

The polysilazane solution for the formation of the second gas barrier layer may be applied by any appropriate wet application process. Specific examples of the wet application process include roller coating, flow coating, ink-jet coating, spray coating, print coating, dip coating, film casting, bar coating, and gravure printing.

A coating layer formed by applying the polysilazane solution may have any appropriate thickness depending on purposes. For example, the dried coating layer should preferably have a thickness in a range of 50 nm to 2 μm, more preferably 70 nm to 1.5 μm, still more preferably 100 nm to 1 μm.

<4.2> Excimer Treatment

At least part of the polysilazane in the second gas barrier layer according to the present invention is modified into silicon oxynitride by the irradiation with vacuum ultraviolet (VUV) beams.

A plausible mechanism of the modification of the polysilazane coating layer into a specified composition or SiOₓN_{y} during the irradiation process with the vacuum ultraviolet beams will now be described with reference to perhydropolysilazane as an example.

The perhydropolysilazane has a composition represented by —(SiH₂—NH)ₙ—. The perhydropolysilazane also can be represented by SiOₓN_{y}, wherein x=0 and y=1. To satisfy x>0, some external oxygen source is required. Examples of the oxygen source are shown as follows:

(i) Oxygen and water contained in the polysilazane solution

(ii) Oxygen and water in an atmosphere to be incorporated into the coating layer during the drying process

(iii) Oxygen, water, ozone, and singlet oxygen in an atmosphere to be incorporated into the coating layer during the irradiation process with vacuum ultraviolet beams

(iv) Oxygen and water to be transferred in the form of an outgas from the substrate into the coating layer by heat generated in the irradiation process with vacuum ultraviolet beams

(v) Oxygen and water in an oxidizing atmosphere, which is shifted from an unoxidizing atmosphere, to be incorporated into the coating layer during the irradiation process with vacuum ultraviolet beams

The upper limit of y is 1 because it is presumed that nitridation of Si requires very particular conditions compared to oxidation of Si.

The values of x and y basically lie in a range of 2x+3y≦4 in association with atomic bonding of Si, O, and N. After complete oxidation where y=0, the coating layer includes silanol groups, and the value of x may lie in a range of 2<x<2.5.

A plausible reaction mechanism of the perhydropolysilazane which generates silicon oxynitride and silicon oxide during the irradiation process with vacuum ultraviolet beams will now be described.

(1) Dehydrogenation, and Formation of Si—N Bond Caused Thereby

It is presumed that Si—H bonds and N—H bonds in the perhydropolysilazane are relatively readily broken by excitation of the vacuum ultraviolet beams, and recombine into Si—N bonds in an inert atmosphere (sometimes dangling bonds of Si are generated). In other words, these Si—H bonds and N—H bonds are linked into cured SiN_{y} compositions without oxidation. Main chain links of the polymer are not broken. Breakage of Si—H bonds and N—H bonds are promoted by catalysts and heat. The hydrogen radicals H from these bonds are combined into a hydrogen molecule H₂, which are released to the exterior of the film.

(2) Formation of Si—O—Si Bond Caused by Hydrolysis and Dehydration Condensation

The Si—N bonds in the perhydropolysilazane are hydrolyzed by water, and the main chain links of polymers are then broken to form Si—OH bonds. Two Si—OH bonds are dehydrated and condensed to form Si—O—Si bonds, which are cured. Such reactions can also be caused in the air; however, during the irradiation with vacuum ultraviolet beams in an inert atmosphere, the moisture source that can cause these reactions is mainly vapor as outgas from the resin substrate generated by heat of the irradiation. Excess moisture leads to residual Si—OH bonds that are not dehydrated and condensed, and thus the resulting cured film, which has the composition represented by SiO_{2.1}—SiO_{2.3}, exhibits low gas barrier properties.

(3) Direct Oxidation by Singlet Oxygen, and Formation of Si—O—Si Bonds

The irradiation with vacuum ultraviolet beams in an atmosphere containing a predetermined amount of oxygen forms singlet oxygen having significantly high oxidizability. The atoms of H or N in the perhydropolysilazane are replaced with O to form Si—O—Si bonds, which are then cured. It is presumed that breakage of main chain links of the polymers may cause recombination of chemical bonds.

(4) Oxidation Involving Breaking Si—N Bonds by Irradiation or Excitation with Vacuum Ultraviolet Beams

It is presumed that the Si—N bonds are broken by the energy of the vacuum ultraviolet beams, which is greater than the binding energy between Si and N in the perhydropolysilazane, and are oxidized into Si—O—Si and Si—O—N bonds in the presence of an oxygen source, for example, oxygen, ozone, or water in the environment. It is presumed that breakage of main chain links of the polymers may cause recombination of chemical bonds.

The formation of the silicon oxynitride compositions in the polysilazane layer by the irradiation with the vacuum ultraviolet beams can be conducted under the control of oxidation environment which is an appropriate combination of the oxidation mechanisms (1) to (4) described above.

In the irradiating process with the vacuum ultraviolet beams according to the present invention, the coating layer including polysilazane should preferably be irradiated with vacuum ultraviolet beams having an irradiance in a range of 30 to 200 mW/cm², more preferably 50 to 160 mW/cm². Irradiation with vacuum ultraviolet beams having an irradiance of 30 mW/cm² or greater is preferred because it has no risk to reduce modification efficiency. Irradiation with vacuum ultraviolet beams having an irradiance of 200 mW/cm² or less is preferred because it does not cause ablation of the coating layer and damages on the substrate.

The energy of the irradiation with the vacuum ultraviolet beams applied on the coating layer containing polysilazane should preferably be in a range of 200 to 10000 mJ/cm², more preferably 500 to 5000 mJ/cm². A cumulative energy of 200 mJ/cm² or greater can efficiently conduct the modification. A cumulative energy of 10000 mJ/cm² or less does not cause excess modification and can prevent cracking and thermal deformation of the resin substrate.

A source of the vacuum ultraviolet beams should preferably be a rare gas excimer lamp. A rare gas is also referred to as an inert gas because the atoms of Xe, Kr, AR, and Ne do not chemically bond into molecules.

However, excited atoms in the rare gas which are energized by, for example, electric discharge can bond with other atoms into molecules. If the rare gas is xenon, Xe₂*, which is an excited excimer atom, radiates excimer light beams having a wavelength of 172 nm when transitioning to a ground state. This reaction is represented by the following formulae:

e+Xe→Xe*

Xe*+2Xe→Xe₂*+Xe

Xe₂*→Xe+Xe+hν(172 nm)

An advantage of the excimer lamp lies in its high efficiency: the excimer lamp can emit light beams having the same wavelength substantially without unwanted light beams. Since the excimer lamp does not emit unwanted light beams, the excimer lamp can keep the target article at a low temperature. In addition, the excimer lamp can quickly flash because it takes little time to start and restart.

The excimer light beams are generated by a known method using dielectric barrier discharge. The dielectric barrier discharge is generated by applying a high frequency voltage of several ten kilohertz to a gas space between electrodes. A dielectric substance, such as transparent quartz, is disposed between the electrodes. The dielectric barrier discharge is microscopic discharge like lightning, and is called microdischarge. Streamers of the microdischarge reach the surface of a tubular wall (or dielectric substance) to accumulate electric charge, which distinguishes the microdischarge.

The microdischarge propagates over the entire tubular wall and is repeatedly generated and extinguished. This causes flickering of light which can be visually observed. Furthermore, direct and regional irradiation of the tubular wall with the streamers at significantly high temperature may accelerate deterioration of the tubular wall.

The excimer light beams can be effectively generated by electrodeless field discharge, as well as dielectric barrier discharge. The electrodeless field discharge, which is caused by capacitive coupling, is also known as RF discharge. Although the lamp, electrodes, and configuration thereof for the electrodeless field discharge are basically the same as those for the dielectric barrier discharge, a radio frequency to be applied to a space between the electrodes has a bandwidth of several megahertz. The electrodeless field discharge, which can provide discharge stable over space and time, can achieve a long-life lamp without flickering.

In the dielectric barrier discharge, the microdischarge is generated only in the space between the electrodes. To cause the microdischarge in the entire discharge space, the outer electrode should cover the entire outer surface and should be composed of a light-transmissive material to transfer the light to the exterior.

Accordingly, a net of fine metal wire is used as an electrode. Such an electrode, which is composed of ultra-thin metal wire to transmit the light beams, is susceptible to damage caused by ozone in the vacuum ultraviolet beams in an oxygen atmosphere. To avoid the damage, the space surrounding the lamp or the interior of the irradiator needs to be purged with an inert gas, for example, nitrogen, and the irradiator needs to be provided with a synthetic silica window through which the irradiation light beams are transmitted. The synthetic silica window is an expensive consumable article and causes optical loss.

In a double-cylinder lamp having an outer diameter of approximately 25 mm, a noticeable difference is provided between the distance from the portion immediately below the lamp axis to an irradiated surface and the distance from the side of the lamp to an irradiated surface. This causes a considerable difference in illuminance between irradiated portions. Two lamps in close contact with each other thus cannot provide a uniform illuminance distribution. The irradiator having a synthetic silica window can provide a uniform distance to an irradiated surface in an oxygen atmosphere, and thus can provide a uniform illuminance distribution.

Electrodeless field discharge requires no net external electrode. Glow discharge can be spread over the entire discharge space only by placing the external electrode on part of the outer surface of the lamp. The external electrode is generally composed of an aluminum block, serves also as a light reflector, and is disposed on the back surface of the lamp. The lamp for the electrodeless field discharge has an outer diameter as large as that for the dielectric barrier discharge, and is thus required to be provided with synthetic silica in order to provide uniform illuminance distribution.

A maximum advantage of a tubular excimer lamp lies in its simple structure, which has a tubular body containing a gas for generating excimer light beams and the gas is sealed by sealing both edges of the silica tube.

The tubular body of the tubular excimer lamp has an outer diameter of approximately 6 to 12 mm. A tubular body having a larger diameter needs higher voltage to start.

Either the dielectric barrier discharge or the electrodeless field discharge can be applied to the tubular excimer lamp. The electrode may have a flat surface in contact with the lamp. The electrode may have any surface profile conforming to the curved surface of the lamp. The electrode having such a profile can tightly fix the lamp. Such close contact of the electrode with the lamp leads to stable discharge. The electrode may have a curved mirror surface composed of aluminum, the mirror surface also serving as a light reflector.

An Xe excimer lamp, which emits ultraviolet beams having a single short wavelength of 172 nm, has high luminescent efficiency. The excimer light beams have a high oxygen absorption coefficient, and thus can generate high concentrations of radical oxygen atoms and ozone from a slight amount of oxygen.

The light beam having a short wavelength of 172 nm has energy that can dissociate the bonds of organic compounds with high efficiency. These radical oxygen, ozone, and high energy of the ultraviolet radiation can modify the polysilazane layer in a short time.

Compared to a low pressure mercury lamp having a wavelength of 185 nm or 254 nm and plasma cleaning, the Xe excimer lamp exhibits high throughput, which can achieve a short processing time, a decrease in an area for installation of facilities, and irradiation to organic materials and plastic substrates that are susceptible to thermal damage.

Excimer lamps exhibit high luminescent efficiency, and thus can emit light beams with low electric power. The excimer lamps do not emit light having a long wavelength, which lead to an increase in temperature, but radiate energy within an ultraviolet-light range, i.e., a short-wavelength range. This prevents an increase in temperature of the surface of the target article. The excimer lamps are suitable for materials for flexible films, such as PET, that are susceptible to thermal effects.

Ultraviolet irradiation needs to be conducted in the presence of oxygen to cause chemical reactions. In contrast, vacuum ultraviolet irradiation is preferably conducted under a condition of extremely low oxygen concentration, because the efficiency of the ultraviolet irradiation process readily decreases due to absorption by oxygen. Specifically, the oxygen concentration during the vacuum ultraviolet irradiation should preferably be in a range of 10 to 10000 ppm, more preferably 50 to 5000 ppm, and still more preferably 1000 to 4500 ppm.

A dried inert gas is preferably used as a gas for the irradiation atmosphere of the vacuum ultraviolet irradiation. A dried nitrogen gas is particularly preferred in view of costs. The oxygen concentration can be controlled by measuring the flow rates of an oxygen gas and an inert gas that are introduced in the irradiation chamber and altering the flow ratio between them.

[5] Functional Layers

The gas barrier film of the present invention may optionally include one or more functional layers in addition to the essential layers described above.

<5.1> Overcoat Layer

The second gas barrier layer according to the present invention may be covered with an overcoat layer for higher flexibility. Preferred examples of the organic material for the overcoat layer include organic resins, such as organic monomers, organic oligomers, and organic polymers, and organic-inorganic composite resins, such as siloxane having organic groups and monomer, oligomer, and monomer, oligomer, and polymer of silsesquioxane. These organic resins or organic-inorganic composite resins preferably have polymerizable groups or crosslinkable groups. The overcoat layer is preferably formed through a process which involves applying a solution including these organic resins or organic-inorganic composite resins and optional polymerization initiator or crosslinking agent to form a coating layer, and curing the coating layer through a light irradiation treatment or a thermal treatment.

<5.2> Anchor layer

The gas barrier film of the present invention has a conductive layer on one side (back side) of the resin substrate and a gas barrier layer on the opposite side (front side), and also optionally has an anchor layer (also referred to as a clear hard coat layer (CHC layer)) between the resin substrate and the gas barrier layer to improve adhesion between the substrate and the gas barrier layer.

The anchor layer can also reduce contamination of the contacting surface due to migration (so-called bleeding out) of unreacted materials, such as oligomers from inside the resin substrate to the surface when the resin substrate is heated. The anchor layer, on which the gas barrier layer is to be provided, should preferably be smooth and have a surface roughness (Ra) in a range of 0.3 to 3 nm, more preferably in a range of 0.5 to 1.5 nm. A surface roughness Ra of not less than 0.3 nm provides an appropriate smooth surface which facilitates appropriate roller transportation and maintains a proper smoothness during formation of the gas barrier layer by plasma enhanced CVD. A surface roughness Ra of not more than 3 nm can prevent formation of minute defects in the gas barrier layer during formation of a gas barrier layer to achieve high-quality gas barrier properties and adhesion.

The composition of the anchor layer, which requires smoothness, preferably contains thermosetting or light-curing resins such as the resins used for forming the conductive layer described above.

The anchor layer has a thickness in a range of preferably 0.3 to 10 lam, more preferably 0.5 to 5 μm from the view point of controlling the tendency of curling.

<<Electronic Device>>

The gas barrier film according to the present invention is used in an electronic device.

Examples of the electronic device of the present invention include organic electroluminescent panels, organic electroluminescent devices, organic photoelectric convertors, and liquid crystal displays.

[1] Organic EL Panel as Electronic Device

A gas barrier film 1 according to the present invention having a structure illustrated in FIG. 1 can be used in the form of a sealing film to seal, for example, solar cells, liquid crystal displays, or organic EL devices.

FIG. 5 illustrates an exemplary organic EL panel P which is an electronic device including the gas barrier film 1 serving as a sealing film.

With reference to FIG. 5, the organic EL panel P includes the gas barrier film 1, a transparent electrode 6 of, for example, ITO, formed on the gas barrier film 1, an organic EL device 7, which is a body of the electronic device, formed on the gas barrier film 1 with the transparent electrode 6 in between, and a counter film 9 so as to cover the organic EL device 7 with an adhesive layer 8 provided in between. The transparent electrode 6 may be part of the organic EL device 7.

Specifically, the transparent electrode 6 and the organic EL device 7 are formed on a surface on the side where the gas barrier layer 4 and the second gas barrier layer 5 are disposed composing the gas barrier film 1.

The organic EL device 7 of the organic EL panel P is appropriately sealed not to be exposed to moisture vapor and is thus unlikely to be deteriorated. Such an organic EL panel P can be used for a long term. In other words, the organic EL panel P can have a longer service life.

The counter film 9 may be composed of a metal film, such as aluminum foil, or may be replaced with the gas barrier film according to the present invention. The gas barrier film functioning as the counter film 9 may be bonded with the adhesive layer 8 such that the gas barrier layer 4 faces the organic EL device 7.

[2] Organic EL Device

The organic EL device 7 sealed with the gas barrier film 1 in the organic EL panel P will now be described.

Although the following are specific examples of a preferred structure of the organic EL device 7, the list is not exhaustive:

(1) Positive Electrode/Luminescent Layer/Negative Electrode

(2) Positive Electrode/Hole Transport Layer/Luminescent Layer/Negative Electrode

(3) Positive Electrode/Luminescent Layer/Electron Transport Layer/Negative Electrode

(4) Positive Electrode/Hole Transport Layer/Luminescent Layer/Electron Transport Layer/Negative Electrode

(5) Positive Electrode/Positive Electrode Buffer Layer (Hole Injection Layer)/Hole Transport Layer/Luminescent Layer/Electron Transport Layer/Negative Electrode Buffer Layer (Electron Injection Layer)/Negative Electrode.

(2.1) Positive Electrode

Preferred examples of the material for the positive electrode (transparent electrode 6) of the organic EL device 7 include materials having a high work function (4 eV or greater), such as metals, alloys, electrically conductive compounds, and compositions including a mixture thereof. Specific examples of the electrode material include metals, such as Au, and transparent conductive materials, such as CuI, indium tin oxide (ITO), SnO₂, and ZnO. Alternatively, materials, such as IDIXO (In₂O₃—ZnO) may be used that can form an amorphous transparent conductive layer.

The positive electrode may be produced by depositing or sputtering any of these electrode materials into a thin film, and then patterning the thin film into a desired profile by a photolithographic process. If highly accurate patterning is not required, a film having a thickness of approximately 100 μm or greater may be patterned through a mask having a desired profile during the deposition or sputtering.

The positive electrode should preferably have a light-transmittance of 10% or greater to transmit light beams. In addition, the positive electrode should preferably have a sheet resistance of several hundred Ω/sq or less. The thickness of the positive electrode depends on the material of the positive electrode, and is generally selected within a range of 10 to 1000 nm, preferably 10 to 200 nm.

(2.2) Negative Electrode

Preferred examples of the material for the negative electrode of the organic EL device 7 include materials having a low work function (4 eV or less), such as metals (referred to as electron injection metals), alloys, electrically conductive compounds, and compositions including a mixture thereof. Specific examples of the electrode material include sodium, NaK alloys, magnesium, lithium, mixtures of magnesium and copper, mixtures of magnesium and silver, mixtures of magnesium and aluminum, mixtures of magnesium and indium, mixtures of aluminum and aluminum oxide (Al₂O₃), indium, mixtures of lithium and aluminum, and rare earth metals. Among them, appropriate electrode materials for the negative electrode are mixtures of an electron injection metal and a group 2 metal which has a higher and more stable work function than that of the electron injection metal, in view of their electron injection characteristics and resistance to oxidation; for example, a mixture of magnesium and silver, a mixture of magnesium and aluminum, a mixture of magnesium and indium, a mixture of aluminum and aluminum oxide (Al₂O₃), a mixture of lithium and aluminum, and aluminum.

The negative electrode may be produced by depositing or sputtering any of these electrode materials into a film. The negative electrode should preferably have a sheet resistance of several hundred Ω/sq or less. The thickness of the negative electrode is generally selected within a range of 10 nm to 5 μm, preferably 50 to 200 nm. Either the positive electrode or the negative electrode of the organic EL device 7 should advantageously be transparent or translucent to transmit irradiation light beams, in view of enhanced luminance.

A transparent or translucent negative electrode can be formed by laminating any of the transparent conductive materials, which are shown in the description of the positive electrode, on the metal film formed of any of the metals shown in the description of the negative electrode and having a thickness of 1 to 20 nm. Such a transparent or translucent negative electrode can be applied to a device having transparent positive electrode and negative electrode.

(2.3) Injection Layer

Injection layers are categorized into electron injection layers and hole injection layers. The electron injection layer and the hole injection layer may optionally be disposed between the positive electrode and the luminescent layer or the hole transport layer and between the negative electrode and the luminescent layer or the electron transport layer.

An injection layer is disposed between an electrode and an organic layer to decrease driving voltage and increase luminance. Details of the injection layer is disclosed in “Yuki EL Soshi to Sono Kogyoka Saizensen (Organic EL Devices and their Advanced Industrialization)”, Second Edition, Chapter II “Denkyoku Zairyo (Electrode Material)” (pp. 123-166) (published by N.T.S. Co., Ltd., on Nov. 30, 1998), which describes hole injection layers (positive electrode buffer layers) and electron injection layers (negative electrode buffer layers).

Detailed description of positive electrode buffer layers (hole injection layers) are also found in Japanese Unexamined Patent Application Publication Nos. H9-45479, H9-260062, and H8-288069. Specific examples include phthalocyanine buffer layers such as copper phthalocyanine, oxide buffer layers such as vanacium oxide, amorphous carbon buffer layers, and polymer buffer layers composed of conductive polymers, such as polyaniline (emeraldine) and polythiophene.

Detailed description of the negative electrode buffer layers (electron injection layers) are also found in Japanese Unexamined Patent Application Publication Nos. H.6-325871, H9-17574, and H10-74586. Specific examples include metal buffer layers such as strontium and aluminum, alkali metal compound buffer layers such as lithium fluoride, alkaline earth metal compound buffer layers such as magnesium fluoride, and oxide buffer layers such as aluminum oxide. The buffer (injection) layer should preferably be an ultra-thin film. The thickness of the buffer (injection) layer depends on the material thereof, and should preferably be 0.1 nm to 5 μm.

(2.4) Luminescent Layer

The luminescent layer in the organic EL device 7 emits light which is caused by recoupling of electrons and holes injected from the electrodes (negative and positive electrodes), the electron transport layer, or the hole transport layer. The luminescent layer may emit light at the interior of the luminescent layer or the interface between the luminescent layer and an adjacent layer.

The luminescent layer of the organic EL device 7 should preferably contain a luminescent dopant and a luminescent host that will be described below. This leads to higher luminescent efficiency.

<2.4.1> Luminescent Dopant

Luminescent dopants are generally categorized into two types, i.e., fluorescent dopants that generate fluorescence and phosphorescent dopants that generate phosphorescence.

Typical examples of the fluorescent dopant include coumarin pigments, pyran pigments, cyanine pigments, croconium pigments, squalium pigments, oxobenzanthracene pigments, fluorescein pigments, rhodamine pigments, pyrylium pigments, perylene pigments, stilbene pigments, polythiophene pigments, and rare-earth complex phosphors.

Preferred examples of the phosphorescent dopant include complex compounds containing group 8, 9, and 10 metals of the periodic table of elements. More preferred are iridium compounds and osmium compounds, and mostly preferred are iridium compounds.

The luminescent dopant may be a mixture of compounds.

<2.4.2> Luminescent Host

A luminescent host (also simply referred to as host) refers to the most abundant compound (in mass ratio) in a luminescent layer composed of two or more compounds. The other compounds are referred to as “dopant compounds (also simply referred to as dopants)”. For example, in a luminous layer composed of two compounds, i.e., compounds A and B at a ratio of 10:90, compound A is a dopant compound and compound B is a host compound. In a luminous layer composed of three compounds, i.e., compounds A, B, and C at a ratio of 5:10:85, compounds A and B are dopant compounds, and compound C is a host compound.

The luminescent host may have any structure. Typical examples of the structure include a structure having a basic skeleton of carbazole derivatives, triarylamine derivatives, aromatic borane derivatives, nitrogen-containing heterocyclic compounds, thiophene derivatives, furan derivatives, or oligoarylene compounds, carboline derivatives, and diaza carbazole derivatives in which at least one carbon atom of hydrocarbon rings constituting a carboline ring of a carboline derivative is replaced with a nitrogen atom. Among them, preferred are carboline derivatives and diaza carbazole derivatives.

The luminescent layer can be formed with any of the compounds described above through a known deposition process, for example, vacuum deposition, spin coating, casting, Langmuir Blodgett (LB) deposition, or ink-jetting. The luminescent layer may have any thickness, generally in a range of 5 nm to 5 μm, preferably 5 to 200 nm. The luminescent layer may have a monolithic structure composed of one or more dopant compounds and host compounds. Alternatively, the luminescent layer may have a laminate structure composed of homogeneous or heterogeneous layers.

(2.5) Hole Transport Layer

Hole transport layers are composed of a material that can transport holes. In a broad sense, the hole transport layers include hole injection layers and electron blocking layers. One or more hole transport layers may be provided.

Materials for the hole transport layers have hole-injecting or hole-transporting characteristics or electron-barrier characteristics, and may be either organic materials or inorganic materials. Example of the materials include triazole derivatives, oxadiazole derivatives, imidazole derivatives, polyaryl alkane derivatives, pyrazoline derivatives, pyrazolone derivatives, henylenediamine derivatives, arylamine derivatives, amino-substituted chalcone derivatives, oxazole derivatives, styrylanthracene derivatives, fluorenone derivatives, hydrazine derivatives, stilbene derivatives, silazane derivatives, aniline copolymers, and conductive polymer oligomers, such as thiophene oligomers. These materials may be used as hole transport materials, and preferred are porphyrin compounds, aromatic tertiary amine compounds, and styrylamine compounds. Particularly preferred are aromatic tertiary amine compounds. Polymer materials including these hole transport materials in the polymer chains or polymer materials including these hole transport materials in the main chains may also be used. Inorganic compounds, such as p-type Si and p-type SiC, may also be used as hole injection materials and hole transport materials.

The hole transport layer may be formed with any of the hole transporting materials described above through a known deposition process, for example, vacuum deposition, spin coating, casting, printing process including ink-jetting, or Langmuir Blodgett (LB) deposition. The hole transport layer may have any thickness, generally in a range of 5 nm to 5 μm, preferably 5 to 200 nm. The hole transport layer may have a monolithic structure composed of one or more materials selected from the materials described above.

(2.6) Electron Transport Layer

Electron transport layers are composed of a material that can transport electrons. In a broad sense, the electron transport layers include electron injection layers and hole blocking layers. One or more electron transport layers may be provided.

Any materials that can transport electrons injected from the negative electrode to the luminescent layer may be used for the electron transport layers. Any known materials may be selected for the electron transport layers, for example, nitro-substituted fluorene derivatives, diphenylquinone derivatives, thiopyran dioxide derivatives, carbodiimide, fluorenylidene methane derivative, anthraquinodimethane, anthrone derivatives, and oxadiazole derivatives. The electron transport materials may be thiadiazole derivatives, which are the same as the oxadiazole derivatives except that the oxygen atoms of oxadiazole rings are replaced with sulfur atoms, and quinoxaline derivatives having quinoxaline rings, which are known as electron-withdrawing groups. In addition, polymer materials including these electron transport materials in the polymer chains or polymer materials including these electron transport materials in the main chains may be used. Furthermore, the electron transport materials may be metal complexes of 8-quinolinol derivatives, such as tris(8-quinolinol)aluminum (Alq), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum, and bis(8-quinolinol)zinc (Znq), and metal complexes which are the same as the metal complexes of 8-quinolinol derivatives except that they have central metals that are replaced with In, Mg, Cu, Ca, Sn, Ga, or Pb. Examples of other preferred electron transport material include metal-free phthalocyanine and metal phthalocyanine, and metal-free phthalocyanine and metal phthalocyanine of which ends are replaced with alkyl groups or sulfonate groups. Inorganic semiconductors, such as n-type Si and n-type SiC, may be used as electron transport materials, as in the hole injection layers and hole transport layers.

The electron transport layer may be formed with any of the electron transporting materials described above through a known deposition process, for example, vacuum deposition, spin coating, casting, printing process including ink-jetting, or Langmuir Blodgett (LB) deposition. The electron transport layer may have any thickness, generally in a range of 5 nm to 5 μm, preferably 5 to 200 nm. The electron transport layer may have a monolithic structure composed of one or more materials selected from the materials described above.

(2.7) Production of Organic EL Device

A method of producing an organic EL device 7 will now be described.

Specifically, a method of producing an exemplary organic EL device 7 will now be described which includes a positive electrode, a hole injection layer, a hole transport layer, a luminescent layer, an electron transport layer, an electron injection layer, and a negative electrode in sequence.

A positive electrode composed of a desired electrode material, for example, positive electrode materials, and having a thickness of 1 μm or less, preferably in a range of 10 to 200 nm, is formed on a gas barrier film 1 of the present invention through deposition, sputtering, or a plasma-enhanced CVD process, for example.

Functional layers of an organic EL device, i.e., a hole injection layer, a hole transport layer, a luminescent layer, an electron transport layer, and an electron injection layer are formed on the positive electrode through deoisition or a wet process (spin coating, casting, ink-jetting, or printing), for example. Particularly preferred are vacuum deposition, spin coating, ink-jetting, and printing that can readily form uniform and substantially pinhole-free films. Alternatively, each functional layer may be formed by a different process. In the film-formation by deposition, the deposition conditions depend on types of compounds to be used; in general, appropriate conditions should preferably be determined within the following ranges: the boat heating temperature in a range of 50 to 450° C., the degree of vacuum in a range of 1×10⁻⁶ to 1×10⁻² pa, the deposition rate in a range of 0.01 to 50 nm/sec, the temperature of the substrate in a range of −50 to 300° C., the thickness of the resulting film in a range of 0.1 nm to 5 μm, preferably 5 to 200 nm.

After the formation of these functional layers, a negative electrode composed of a negative electrode material and having a thickness of 1 μm or less, preferably in a range of 50 to 200 nm, is formed on the functional layers through deposition or sputtering, for example, to form a desired organic EL device.

In the formation of the organic EL device, the workpiece including the positive electrode, the hole injection layer, and the negative electrode should preferably be formed through a single vacuum process. Alternatively, the workpiece may be formed through a combination of the vacuumed process and other film-forming processes. In this case, the organic EL device should be formed in a dried inert gas atmosphere. The functional layers of the organic EL device may be formed in a reversed order, i.e., a negative electrode, an electron injection layer, an electron transport layer, a luminescent layer, a hole transport layer, a hole injection layer, and a positive electrode.

A color display (organic EL panel) including the resulting organic EL device emits light in response to the application of a DC voltage in the range of approximately 2 to 40 V across the anode (positive polarity) and the cathode (negative polarity). Alternatively, an AC voltage may be applied. The AC voltage may have any AC waveform.

### EXAMPLES

The present invention will now be described in detail with non-limiting examples. In the examples, the terms “parts” and “%” represent “parts by mass” and “mass %”, respectively, unless otherwise mentioned.

### Example 1

### Preparation of Resin Substrate

A polyester film (manufactured by Teijin DuPont Films Japan Limited, poly(ethylene terephthalate), KDL86WA, abbreviated as “PET” in Table 1) having a thickness of 125 μm, both faces of which were treated to be readily adhesive, was used to form a thermoplastic resin substrate (support). The surface roughness Ra and Rz (measured in accordance with JIS B0601) of the resin substrate were 4 nm and 320 nm, respectively.

<<Fabrication of Resin Substrate Provided with Conductive Layer Thereon>>

[Fabrication of Resin Substrate 1 Provided with Conductive Layer Thereon]

A 150-nm thick ITO (indium tin oxide) layer as a conductive layer was formed on the second surface of the resin substrate through sputtering into a resin substrate 1 provided with a conductive layer thereon.

[Fabrication of Resin Substrate 2 Provided with Conductive Layer Thereon]

The following conductive layer forming coating solution 2 was applied to the second surface of the resin substrate through wire-bar coating, dried at 80° C. for three minutes into a dry thickness of 4 μm, and then cured with light having an energy of 0.5 J/cm² in air from a high-pressure mercury lamp to form a resin substrate 2 provided with a conductive layer thereon.

(Preparation of Conductive Layer Forming Coating Solution 2)

To a UV-curable resin, UNIDIC V-4025 manufactured by DIC Corporation were added a NanoTek Slurry (dispersion of SnO₂ in methyl isobutyl ketone (MIBK) manufactured by C.I. Kasei Co., Ltd.) at a volume ratio (volume %) of the UV-curable resin to SnO₂ of 85:15 in solid content and then a photopolymerization initiator, IRGACURE 184 (manufactured by BASF Japan Ltd.), at a mass ratio (mass %) of the UV-curable resin to the photopolymerization initiator of 95:5 in solid content to prepare a conductive layer forming coating solution 2.

[Fabrication of Resin Substrate 3 Provided with Conductive Layer Thereon]

A resin substrate 3 provided with a conductive layer thereon was formed as in the resin substrate 2 provided with the conductive layer thereon, except that the conductive layer forming coating solution 2 was replaced with a conductive layer forming coating solution 3 which was prepared as in the solution 2, except that the added amount ratio (volume %) of the UV-curable resin to SnO₂ was 96:4.

[Fabrication of Resin Substrate 4 Provided with Conductive Layer Thereon]

A resin substrate 4 provided with a conductive layer thereon was formed as in the resin substrate 2 provided with the conductive layer thereon, except that the conductive layer forming coating solution 2 was replaced with a conductive layer forming coating solution 4 which was prepared as in the solution 2, except that the SnO₂ dispersion was replaced with a polythiophene, SEPLEGYDA AS-H manufactured by Shin-Etsu Polymer Co., Ltd. and the mass ratio (volume %) of the UV-curable resin to the conductive polymer was 90:10 in solid content.

[Fabrication of Resin Substrate 5 Provided with Conductive Layer Thereon]

A resin substrate 5 provided with a conductive layer thereon was formed as in the resin substrate 2 provided with the conductive layer thereon, except that the conductive layer forming coating solution 2 was replaced with a conductive layer forming coating solution 5 which was prepared as in the solution 2, except that the SnO₂ dispersion was not added.

[Fabrication of Resin Substrate 6 Provided with Conductive Layer Thereon]

A resin substrate 6 provided with a conductive layer thereon was formed as in the resin substrate 2 provided with the conductive layer thereon, except that the conductive layer forming coating solution 2 was replaced with a conductive layer forming coating solution 6 which was prepared as in the solution 2, except that the added amount ratio (volume %) of the UV-curable resin to SnO₂ was 60:40.

[Fabrication of Resin Substrate 7 Provided with Conductive Layer Thereon]

A resin substrate 7 provided with a conductive layer thereon was formed as in the resin substrate 2 provided with the conductive layer thereon, except that the conductive layer forming coating solution 2 was replaced with a conductive layer forming coating solution 7 which was prepared as in the solution 2, except that the added amount ratio (volume %) of the UV-curable resin to SnO₂ was 93:7.

[Fabrication of Resin Substrate 8 Provided with Conductive Layer Thereon]

A resin substrate 8 provided with a conductive layer thereon was formed as in the resin substrate 2 provided with the conductive layer thereon, except that the conductive layer forming coating solution 2 was replaced with a conductive layer forming coating solution 8 which was prepared as in the solution 2, except that the SnO₂ dispersion was replaced with a polythiophene, SEPLEGYDA AS-H manufactured by Shin-Etsu Polymer Co., Ltd.

[Fabrication of Resin Substrate 9 Provided with Conductive Layer Thereon]

A resin substrate 9 provided with a conductive layer thereon was formed as in the resin substrate 2 provided with the conductive layer thereon, except that the conductive layer forming coating solution 2 was replaced with a conductive layer forming coating solution 9 which was prepared as in the solution 2, except that the SnO₂ dispersion was replaced with NanoTek Slurry (a dispersion of ITO in methyl isobutyl ketone (MIBK) manufactured by C.I. Kasei Co., Ltd.).

[Fabrication of Resin Substrate 10 Provided with Conductive Layer Thereon]

A resin substrate 10 provided with a conductive layer thereon was formed as in the resin substrate 2 provided with the conductive layer thereon, except that the conductive layer forming coating solution 2 was replaced with a conductive layer forming coating solution 10 which was prepared as in the solution 2, except that the UV-curable resin was replaced with OPSTAR Z7501 manufactured by JRS Corporation and the SnO₂ dispersion was replaced with NanoTek Slurry (dispersion of ITO in methyl isobutyl ketone (MIBK) manufactured by C.I. Kasei Co., Ltd.).

[Fabrication of Resin Substrate 11 Provided with Conductive Layer Thereon]

After a conductive layer was formed with the conductive layer forming coating solution 10 on a resin substrate as in the resin substrate 10 provided with the conductive layer thereon, a UV-curable resin, OPSTAR Z7501 manufactured by JRS Corporation, was applied to the surface (first surface) opposite the surface on which the conductive layer was provided of the resin substrate through wire-bar coating, dried at 80° C. for three minutes into a dry thickness of 4 μm, and then cured with light having an energy of 0.5 J/cm² in air from a high-pressure mercury lamp to form an anchor layer, thereby forming a resin substrate 11 provided with a conductive layer thereon.

[Fabrication of Resin Substrate 12 Provided with Conductive Layer Thereon]

A resin substrate 12 provided with a conductive layer thereon was formed as in the resin substrate 10 provided with the conductive layer thereon, except that the polyethylene terephthalate film forming the resin substrate was replaced with a polyethylene naphthalate film, Q65FWA (manufactured by Teijin DuPont Films Japan Limited, abbreviated as “PEN” in Table 1) having a thickness of 125 μm, both faces of which were treated to be readily adhesive.

[Fabrication of Resin Substrate 13 Provided with Conductive Layer Thereon]

A resin substrate 13 provided with a conductive layer thereon was formed as in the resin substrate 10 provided with the conductive layer thereon, except that the polyethylene terephthalate film forming the resin substrate was replaced with a polycarbonate film, WR-S148 (manufactured by Teijin Chemicals Ltd., abbreviated as “PC” in Table 1) having a thickness of 50 μm.

[Fabrication of Resin Substrate 14 Provided with Conductive Layer Thereon]

A resin substrate 14 provided with a conductive layer thereon was formed as in the resin substrate 12 provided with the conductive layer thereon, except that a UV-curable resin, OPSTAR Z7501 manufactured by JRS Corporation was applied to the surface opposite the surface on which the conductive layer was provided (first surface) of the resin substrate through wire-bar coating, dried at 80° C. for three minutes into a dry thickness of 4 μm, and then cured with light having an energy of 0.5 J/cm² in air from a high-pressure mercury lamp to form an anchor layer.

[Fabrication of Resin Substrate 15 Provided with Conductive Layer Thereon]

A resin substrate 15 provided with a conductive layer thereon was formed as in the resin substrate 5 provided with the conductive layer thereon (SnO₂-free conductive layer), except that the conductive layer forming coating solution 2 used in the fabrication of the resin substrate 2 provided with the conductive layer thereon was applied to the surface opposite the surface on which the conductive layer was provided (first surface) of the resin substrate and dried in the same way to form an anchor layer.

<<Fabrication of Gas Barrier Film>>

[Fabrication of Gas Barrier Film 1]

A gas barrier layer was formed on the first surface (surface opposite the surface on which the conductive layer was provided) of the resin substrate 1 provided with the conductive layer thereon using a plasma enhanced CVD system involving plasma discharge in an applied magnetic field between rollers as illustrated in FIG. 2 to form a gas barrier film 1. Such a deposition process is referred to as “roller CVD process”.

The resin substrate 1 provided with the conductive layer thereon was placed in the device such that the surface on which the conductive layer was provided came into contact with deposition rollers under the deposition conditions (plasma CVD conditions) described below to form a gas barrier layer 1 having a thickness of 500 nm on the resin substrate. A gas barrier film 1 was thereby fabricated.

(Deposition Conditions)

Feeding rate of raw material gas (hexamethyldisiloxane, HMDSO): 50 sccm (standard cubic centimeter per minute)

Feeding rate of oxygen gas (O₂): 500 sccm

Degree of vacuum in vacuum chamber: 3 Pa

Power applied from power source to generate plasma: 0.8 kW

Frequency of power source to generate plasma: 70 kHz

Conveying rate of resin substrate provided with conductive layer thereon: 0.8 m/min

[Fabrication of Gas Barrier Film 2]

A 500-nm thick gas barrier layer 2 composed of a first ceramic layer and a second ceramic layer was formed on the first surface (surface opposite the surface on which the conductive layer was provided) of the resin substrate 2 provided with the conductive layer thereon through a plasma discharge process under the following conditions. Such a deposition process is referred to as “CVD process”.

(Formation of First Ceramic Layer)

<Mixed gas composition for forming first ceramic layer>

| | |
|---|---|
| Discharge gas: nitrogen gas | 94.9 volume % |
| Thin film forming gas: tetraethoxysilane | 0.5 volume % |
| Additive gas: oxygen gas | 5.0 volume % |

(Conditions for Forming First Ceramic Layer)

For the first electrode:
Power supply: product of OYO Electric Co., Ltd., 80 kHz
Frequency: 80 kHz
Power density: 8 W/cm²
Electrode temperature: 120° C.

For the second electrode:
Power supply: CF-5000-13M of PEARL KOGYO Co., Ltd., 13.56 MHz
Frequency: 13.56 MHz
Power density: 10 W/cm²
Electrode temperature: 90° C.

(Formation of Second Ceramic Layer)

<Mixed gas composition for forming second ceramic layer>

| | |
|---|---|
| Discharge gas: nitrogen gas | 94.9 volume % |
| Thin film forming gas: tetraethoxysilane | 0.1 volume % |
| Additive gas: oxygen gas | 5.0 volume % |

(Conditions for Forming Second Ceramic Layer)

For the first electrode:
Power supply: PHF-6k of MAIDEN LABORATORY, 100 kHz (continuous mode)
Frequency: 100 kHz
Power density: 10 W/cm²
Electrode temperature: 120° C.

For the second electrode:
Power supply: CF-5000-13M of PEARL KOGYO Co., Ltd., 13.56 MHz
Frequency: 13.56 MHz
Power density: 10 W/cm²
Electrode temperature: 90° C.

[Fabrication of Gas Barrier Film 3]

A 500-nm thick gas barrier layer composed of SiO₂ was formed on the first surface (surface opposite the surface on which the conductive layer was provided) of the resin substrate 2 provided with the conductive layer thereon through a known sputtering process under the following conditions to fabricate a gas barrier film 3. Such a deposition process is referred to as “sputtering process”.

[Fabrication of Gas Barrier Film 4]

SiO₂ placed in a resistive heating boat was electrically heated in a vacuum evaporation apparatus and deposited at a deposition rate of 1 to 2 nm/sec into a 500-nm thick gas barrier layer composed of SiO₂ on the first surface (surface opposite the surface on which the conductive layer was provided) of the resin substrate 2 provided with the conductive layer thereon. A gas barrier film 4 was thereby fabricated.

[Fabrication of Gas Barrier Film 5]

A 300-nm thick gas barrier layer was formed on the first surface (surface opposite the surface on which the conductive layer was provided) of the resin substrate 2 provided with the conductive layer thereon through a PHPS-excimer process to fabricate a gas barrier film 5. Such a deposition process is referred to as “PHPS-excimer process (abbreviated as “Excimer process” in Table 1)”.

(Formation of SiO₂ Film from Polysilazane)

<Preparation of Coating Solution for Forming Polysilazane Layer>

A solution of 10 mass % perhydropolysilazane (uncatalyzed Aquamica NN120-10 manufactured by AZ Electronic Materials) in dibutyl ether was used as a coating solution for forming a polysilazane layer.

<Formation of Polysilazane Layer>

The coating solution for forming the polysilazane layer was applied with a wireless bar into an average dry thickness of 300 nm, which was dried for one minute in an atmosphere at a temperature of 85° C. and a humidity of 55% RH and then dehumidified for 10 minutes in an atmosphere at a temperature of 25° C. and a humidity of 10% RH (dew-point temperature of −8° C.) to form a polysilazane layer.

<Formation of Gas Barrier Layer: Silica Conversion of Polysilazane Layer with Ultraviolet Light>

The polysilazane layer was subjected to silica conversion using the ultraviolet irradiation apparatus below, which was placed in a vacuum chamber to control the interior pressure of the apparatus.

<Ultraviolet Irradiation Apparatus>

Apparatus: Excimer irradiation apparatus, MECL-M-1-200 manufactured by M. D. COM, Inc.

Irradiation wavelength: 172 nm

Gas in Lamp: xenon

<Conditions for Modification>

The resin substrate 2 provided with the conductive layer and the polysilazane layer thereon, which was fixed onto a movable stage of the apparatus, was modified under the following conditions to form a gas barrier layer. A gas barrier film 5 was thereby fabricated.

Light intensity of excimer lamp: 130 mW/cm² (172 nm)

Distance between sample and light source: 1 mm

Heating temperature of stage: 70° C.

Oxygen content in apparatus: 1.0%

Irradiation time of excimer lamp: 5 seconds

[Fabrication of gas barrier films 6 to 18]

Gas barrier films 6 to 18 were fabricated as in the gas barrier film 1 through a roller CVD process, except that the resin substrate 1 provided with the conductive layer thereon was replaced with the resin substrates 2 to 5, 15, 6 to 13 provided with the conductive layers thereon, respectively.

[Fabrication of Gas Barrier Film 19]

A 300 nm-thick gas barrier layer was formed as in the gas barrier film 6 through a roller CVD process, except that the amount of oxygen gas supplied was 750 sccm and the conveying rate of the film was 2.5 m/min to fabricate a gas barrier film 19.

[Fabrication of Gas Barrier Film 20]

A 1,000 nm-thick gas barrier layer was formed as in the gas barrier film 6 through a roller CVD process, except that the amount of the raw material gas supplied was 75 sccm and the conveying rate of the film was 0.4 m/min to fabricate a gas barrier film 20.

[Fabrication of Gas Barrier Film 21]

A 300 nm-thick gas barrier layer was formed as in the gas barrier film 15 through a roller CVD process, except that the amount of oxygen gas supplied was 750 sccm and the conveying rate of the film was 2.5 m/min to fabricate a gas barrier film 21.

[Fabrication of Gas Barrier Film 22]

A 1,000 nm-thick gas barrier layer was formed as in the gas barrier film 15 through a roller CVD process, except that the amount of the raw material gas supplied was 75 sccm and the conveying rate of the film was 0.4 m/min to fabricate a gas barrier film 22.

[Fabrication of Gas Barrier Film 23]

An overcoat layer was formed over the gas barrier layer of the gas barrier film 17 through the process below to fabricate a gas barrier film 23.

(Formation of Overcoat Layer)

WASHIN COAT MP6103 manufactured by Washin Chemical Industry Co., Ltd. was applied over the gas barrier layer of the gas barrier film 17 into a dry thickness of 500 nm and then dried at 120° C. for three minutes to form an overcoat layer.

[Fabrication of Gas Barrier Film 24]

A 300 nm-thick second gas barrier layer was formed on the gas barrier layer of the gas barrier film 17 as in the gas barrier film 5 through a PHPS-excimer process to fabricate a gas barrier film 24.

[Fabrication of Gas Barrier Film 25]

Another identical 500 nm-thick gas barrier layer (second gas barrier layer) was deposited on the gas barrier layer of the gas barrier film 17 to a total thickness of 1,000 nm. A gas barrier film 25 was thereby fabricated.

[Fabrication of Gas Barrier Film 26]

An overcoat layer was formed over the second gas barrier layer of the gas barrier film 24 through the process below to fabricate a gas barrier film 26.

(Formation of Overcoat Layer)

WASHIN COAT MP6103 manufactured by Washin Chemical Industry Co., Ltd. was applied over the second gas barrier layer of the gas barrier film 24 into a dry thickness of 500 nm and then dried at 120° C. for three minutes to form an overcoat layer.

[Fabrication of Gas Barrier Film 27]

An overcoat layer was formed over the second gas barrier layer of the gas barrier film 24 through the process below to fabricate a gas barrier film 27.

(Formation of Overcoat Layer)

GLASCA HPC7003 manufactured by JSR Corporation was applied over the second gas barrier layer of the gas barrier film 24 into a dry thickness of 500 nm and then dried at 120° C. for three minutes to form an overcoat layer.

[Fabrication of Gas Barrier Film 28]

A gas barrier film 28 was fabricated as in the gas barrier film 26, except that the resin substrate 12 provided with the conductive layer thereon was replaced with the resin substrate 14 provided with the conductive layer (and an anchor layer) thereon.

The configuration of each gas barrier film is shown in Table 1.

TABLE 1

| | RESIN SUBSTRATE PROVIDED WITH CONDUCTIVE LAYER | | | | | | GAS BARRIER |
|---|---|---|---|---|---|---|---|
| | (ON SECOND SURFACE) | | | | | | LAYER UNIT |
| | | | CONDUCTIVE LAYER | | | | (ON FIRST SURFACE) |
| GAS | | | | | SPECIFIC | | GAS BARRIER |
| BARRIER | | SUBSTRATE | | | SURFACE | | LAYER |
| FILM | | RESIN | RESIN | METAL | RESISTIVITY | ANCHOR | TYPE OF |
| NUMBER | NUMBER | MATERIAL | MATERIAL | OXIDE | (Ω/□) | LAYER | DEPOSITION |
| 1 | 1 | PET | — | ITO | 2 × 10² | — | ROLLER CVD |
| 2 | 2 | PET | V-4025 | SnO₂ | 5 × 10⁷ | — | CVD |
| 3 | 2 | PET | V-4025 | SnO₂ | 5 × 10⁷ | — | SPUTTERING |
| 4 | 2 | PET | V-4025 | SnO₂ | 5 × 10⁷ | — | VACUUM |
| | | | | | | | DEPOSITION |
| 5 | 2 | PET | V-4025 | SnO₂ | 5 × 10⁷ | — | EXCIMER |
| | | | | | | | TREATMENT |
| 6 | 2 | PET | V-4025 | SnO₂ | 5 × 10⁷ | — | ROLLER CVD |
| 7 | 3 | PET | V-4025 | SnO₂ | 3 × 10¹¹ | — | ROLLER CVD |
| 8 | 4 | PET | V-4025 | AS—H | 5 × 10¹² | — | ROLLER CVD |
| 9 | 5 | PET | V-4025 | — | 8 × 10¹³ | — | ROLLER CVD |
| 10 | 15 | PET | V-4025 | — | 8 × 10¹³ | * 1 | ROLLER CVD |
| 11 | 6 | PET | V-4025 | SnO₂ | 4 × 10⁴ | — | ROLLER CVD |
| 12 | 7 | PET | V-4025 | SnO₂ | 6 × 10⁹ | — | ROLLER CVD |
| 13 | 8 | PET | V-4025 | AS—H | 5 × 10⁹ | — | ROLLER CVD |
| 14 | 9 | PET | V-4025 | ITO | 2 × 10⁷ | — | ROLLER CVD |
| 15 | 10 | PET | V-4025 | ITO | 2 × 10⁷ | — | ROLLER CVD |
| 16 | 11 | PET | V-4025 | ITO | 2 × 10⁷ | Z7501 | ROLLER CVD |
| 17 | 12 | PEN | V-4025 | ITO | 2 × 10⁷ | — | ROLLER CVD |
| 18 | 13 | PC | V-4025 | ITO | 2 × 10⁷ | — | ROLLER CVD |
| 19 | 2 | PET | V-4025 | SnO₂ | 5 × 10⁷ | — | ROLLER CVD |
| 20 | 2 | PET | V-4025 | SnO₂ | 5 × 10⁷ | — | ROLLER CVD |
| 21 | 10 | PET | V-4025 | ITO | 2 × 10⁷ | — | ROLLER CVD |
| 22 | 10 | PET | V-4025 | ITO | 2 × 10⁷ | — | ROLLER CVD |
| 23 | 12 | PEN | V-4025 | ITO | 2 × 10⁷ | — | ROLLER CVD |
| 24 | 12 | PEN | V-4025 | ITO | 2 × 10⁷ | — | ROLLER CVD |
| 25 | 12 | PEN | V-4025 | ITO | 2 × 10⁷ | — | ROLLER CVD |
| 26 | 12 | PEN | V-4025 | ITO | 2 × 10⁷ | — | ROLLER CVD |
| 27 | 12 | PEN | V-4025 | ITO | 2 × 10⁷ | — | ROLLER CVD |
| 28 | 14 | PEN | V-4025 | ITO | 2 × 10⁷ | Z7501 | ROLLER CVD |
| | | GAS BARRIER LAYER UNIT (ON FIRST SURFACE) | | | | | |
| | GAS | GAS BARRIER | SECOND GAS | | OVERCOAT | | |
| | BARRIER | LAYER | BARRIER LAYER | | LAYER | | |
| | FILM | THICKNESS | TYPE OF | THICKNESS | RESIN | THICKNESS | |
| | NUMBER | (nm) | DEPOSITION | (nm) | MATERIAL | (nm) | REMARKS |
| | 1 | 500 | — | — | — | — | COMPARATIVE |
| | 2 | 500 | — | — | — | — | COMPARATIVE |
| | 3 | 500 | — | — | — | — | COMPARATIVE |
| | 4 | 500 | — | — | — | — | COMPARATIVE |
| | 5 | 300 | — | — | — | — | COMPARATIVE |
| | 6 | 500 | — | — | — | — | INVENTIVE |
| | 7 | 500 | — | — | — | — | COMPARATIVE |
| | 8 | 500 | — | — | — | — | COMPARATIVE |
| | 9 | 500 | — | — | — | — | COMPARATIVE |
| | 10 | 500 | — | — | — | — | COMPARATIVE |
| | 11 | 500 | — | — | — | — | INVENTIVE |
| | 12 | 500 | — | — | — | — | INVENTIVE |
| | 13 | 500 | — | — | — | — | INVENTIVE |
| | 14 | 500 | — | — | — | — | INVENTIVE |
| | 15 | 500 | — | — | — | — | INVENTIVE |
| | 16 | 500 | — | — | — | — | INVENTIVE |
| | 17 | 500 | — | — | — | — | INVENTIVE |
| | 18 | 500 | — | — | — | — | INVENTIVE |
| | 19 | 300 | — | — | — | — | INVENTIVE |
| | 20 | 1000 | — | — | — | — | INVENTIVE |
| | 21 | 300 | — | — | — | — | INVENTIVE |
| | 22 | 1000 | — | — | — | — | INVENTIVE |
| | 23 | 500 | — | — | MP6103 | 500 | INVENTIVE |
| | 24 | 500 | EXCIMER | 300 | — | — | INVENTIVE |
| | | | TREATMENT | | | | |
| | 25 | 500 | ROLLER CVD | 500 | — | — | INVENTIVE |
| | 26 | 500 | EXCIMER | 300 | MP6103 | 500 | INVENTIVE |
| | | | TREATMENT | | | | |
| | 27 | 500 | EXCIMER | 300 | GLASCA | 500 | INVENTIVE |
| | | | TREATMENT | | | | |
| | 28 | 500 | EXCIMER | 300 | MP6103 | 500 | INVENTIVE |
| | | | TREATMENT | | | | |

* 1: 1:V-4025/SnO₂ (SPECIFIC SURFACE RESISTIVITY: 5 × 10⁷)

The components abbreviated in Table 1 and the details of how to measure specific surface resistivity are as follows:

(Resin Materials)

PET: poly(ethylene terephthalate)

PEN: poly(ethylene naphthalate)

PC: polycarbonate

(Conductive Layer on Second Surface)

<Resin>

V-4025: UV-curable resin, UNIDIC V-4025 manufactured by DIC Corporation

Z7501: UV-curable resin, OPSTAR Z7501 manufactured by JSR Corporation

AS-H: SEPLEGYDAAS-H (polythiophene-based) manufactured by Shin-Etsu Polymer Co., Ltd.

<Metal Oxide>

ITO: indium tin oxide

(Overcoat Layer)

MP6103: WASHIN COAT MP6103 manufactured by Washin Chemical Industry Co., Ltd.

GLASCA: GLASCA HPC7003 manufactured by JSR Corporation

(Measurement of Specific Surface Resistivity)

After the resin substrates provided with the conductive layers thereon were humidified in an environment at 23° C. and 50% RH for 24 hours, the conductive layers were connected to a measurement electrode and a digital ultrahigh resistance meter (R8340A) manufactured by ADVANTEST CORPORATION was used to measure the specific surface resistivity at an applied voltage of 100 V in an environment at 23° C. and 50% RH. Numerals represent the mean values of n=5.

<<Measurement and Evaluation of Characteristic Values of Gas Barrier Films>>

[Measurement of Atom Distribution Profile (XPS Data)]

XPS depth profiles of the fabricated gas barrier films were measured under the following conditions to obtain the silicon, oxygen, carbon, and oxygen-carbon atom distribution.

Etching ion species: argon (Ar⁺)

Etching rate (in terms of SiO₂ thermal oxide film): 0.05 nm/sec

Etching interval (in terms of SiO₂): 10 nm

X-ray photoelectron spectrometer: “VG Theta Probe” model manufactured by Thermo Fisher Scientific Inc.

X-ray irradiation: single-crystal monochromatized AlKα

Spot shape and size of X-ray: oval in size of 800×400 μm.

Table 1 indicates the maximum atomic percentage of silicon across each gas barrier layer; the maximum atomic percentage of oxygen across each gas barrier layer; the maximum atomic percentage of carbon and whether the atomic percentage of carbon continuously varied or not within a region from the surface of each gas barrier layer to a depth of 89% of the thickness; and the maximum atomic percentage of carbon and whether the atomic percentage of carbon continuously increased or not within a region from 90% to 95% from the surface of each gas barrier layer in a perpendicular direction (within a region of 5% to 10% in the perpendicular direction from the surface adjacent to the resin substrate).

Based on the data measured under the conditions above, a graph in FIG. 3 shows example silicon, oxygen, and carbon distribution curves versus the distance from the surface of each gas barrier layer (the horizontal axis), in a gas barrier film 15 of the present invention described in Table 1 below.

[Measurement of Water Vapor Transmission Rate (WVTR) (Evaluation of Sample Immediately after Fabrication)]

The water vapor transmission rate (WVTR) of each gas barrier film was measured in accordance with the process using calcium as described below.

(Apparatus for Fabricating Samples for Evaluation of Water Vapor Barrier)

Deposition apparatus: vacuum deposition apparatus, JEE-400 manufactured by JEOL Ltd.

Thermo-hygrostat oven: Yamato Humidic Chamber IG47M

<Raw Materials>

Metal corroding by reaction with water: calcium (granules)

Metal impermeable to water vapor: aluminum (granules having a diameter of 3 to 5 mm)

(Fabrication of Sample for Evaluation of Water Vapor Barrier Characteristic)

The vacuum deposition apparatus (vacuum deposition apparatus JEE-400 manufactured by JEOL Ltd.) was used to deposit metal calcium in a size of 12 mm×12 mm through a mask on the gas barrier layer of each fabricated gas barrier film. The thickness of deposited film was controlled to be 80 nm.

The mask was removed under the vacuum, and aluminum was deposited onto the entire surface of the layer to seal temporarily. The vacuum was then released and a dry nitrogen atmosphere was quickly introduced, a 0.2-mm thick quartz glass was bonded to the aluminum deposited surface with UV-curable resin for sealing (manufactured by Nagase ChemteX Corporation), and the resin was irradiated with ultraviolet rays to cure and bond the resin for sealing, to fabricate a sample for evaluation of water vapor barrier.

The resulting samples were stored at a high temperature of 60° C. and a high humidity of 90% RH, and then the development of corrosion of the metal calcium over time was observed. The observation was performed every hour up to six hours from the start of the storage, every three hours up to 24 hours, every six hours up to 48 hours, and every twelve hours thereafter. The ratio (%) of the corroded metal calcium area to the metal calcium deposition area of 12 mm×12 mm was calculated. The observed results were linearly interpolated to determine the time at which the ratio was 1%. The water vapor transmission rate of each gas barrier film was calculated from the relationship among the metal calcium deposition area, the amount of water vapor that corrodes 1% of the metal calcium area, and the time required for the corrosion.

[Evaluation of Adhesion (Evaluation of Samples Immediately after Fabrication)]

The adhesion of each gas barrier layer was evaluated by a cross-cut adhesion test in accordance with JIS K 5600-5.6 (2004 edition).

The surface of the gas barrier layer formed on each gas barrier film was incised into 100 squares of 1 mm² with a cutter knife and a 1 mm-calibrated cutter guide in a depth to reach the resin substrate. A cellophane adhesive tape (“CT405AP-18” manufactured by Nichiban Co. Ltd.; 18 mm in width) was applied over the incisions and rubbed with a pencil eraser to be tightly bonded. The tape was then vertically peeled off. The number of squares remaining on the resin substrate among 100 squares was counted. Adhesion was evaluated in accordance with the following criteria:

GOOD: 4 or less square flakes peeled off in the test.
GOOD-FAIR: 5 to 10 square flakes peeled off in the test.
FAIR: 11 to 15 square flakes peeled off in the test.
FAIR-POOR: 16 to 20 square flakes peeled off in the test.
POOR: 21 to 30 square flakes peeled off in the test.
VERY POOR: 31 or more square flakes peeled off in the test.

[Evaluation of Durability]

In the first step, each gas barrier film was subjected to accelerated deteriorating test in an environment at a high temperature of 85° C. and a high humidity of 85% RH for 3,000 hours.

In the second step, each gas barrier film was wound around a metal cylinder in such a manner that the surface provided of the gas barrier layer faced outside and then left for one minute to test the flexibility.

The gas barrier films, which were subjected to the above process, were measured for water vapor transmission rate (WVTR) and evaluated for adhesion in the same manner as above.

Although the curvature radius R in a flexibility test corresponds to half the diameter of the rod, the curvature radius R was defined as half the diameter of the wound film when a gas barrier film was wound around several laps. The R was 8 mm in the flexibility test.

The results are shown in Table 2.

| | | | | | | | | EFFICIENCY | | | | |
|---|---|---|---|---|---|---|---|---|---|---|---|---|
| | | | | | | | | IMMEDIATELY | | EVALUATION | | |
| | RESIN | ATOM DISTRIBUTION | | | | | | AFTER | | OF DURABILITY | | |
| | SUB- | PROFILE IN GAS BARRIER LAYER | | | | | | FABRICATION | | (AFTER | | |
| GAS | STRATE | | | CARBON ATOM PROFILE | | | | WATER | | ACCELERATED | | |
| BAR- | WITH | | | REGION FROM | | | | VAPOR | | DETERIORATING) | | |
| RIER | CON- | SIL- | OXY- | SURFACE | | REGION FROM | | TRANS- | | WATER VAPOR | | |
| FILM | DUCTIVE | ICON | GEN | TO 89% | | 90% TO 95% | | MISSION | | TRANSMISSION | | |
| NUM- | LAYER | ATOM | ATOM | | CONTINUOUS | | CONTINUOUS | RATE | ADHE- | RATE | ADHE- | |
| BER | NUMBER | *A | *A | *B | VARIATION | *B | INCREASE | (Ω/□) | SION | (Ω/□) | SION | REMARKS |
| 1 | 1 | 32 | 64 | 4 | VARIED | 3 | INCREASED | 3.0 × 10⁻⁴ | FAIR- | 3.0 × 10⁻¹ | VERY | COM- |
| | | | | | | | | | POOR | | POOR | PARATIVE |
| 2 | 2 | 30 | 65 | 5 | NOT | 8 | NOT | 5.0 × 10⁻⁴ | FAIR- | 1.0 × 10⁻¹ | VERY | COM- |
| | | | | | | | | | POOR | | POOR | PARATIVE |
| 3 | 2 | 33 | 67 | 0 | NOT | 0 | NOT | 1.0 × 10⁻⁴ | FAIR- | 3.0 × 10⁻² | VERY | COM- |
| | | | | | | | | | POOR | | POOR | PARATIVE |
| 4 | 2 | 35 | 65 | 0 | NOT | 0 | NOT | 5.0 × 10⁻⁴ | FAIR- | 6.0 × 10⁻¹ | VERY | COM- |
| | | | | | | | | | POOR | | POOR | PARATIVE |
| 5 | 2 | 35 | 65 | 0 | NOT | 0 | NOT | 1.5 × 10⁻⁴ | GOOD | 1.0 × 10⁻² | VERY | COM- |
| | | | | | | | | | | | POOR | PARATIVE |
| 6 | 2 | 26 | 59 | 15 | VARIED | 32 | INCREASED | 1.0 × 10⁻⁴ | GOOD | 6.0 × 10⁻³ | GOOD- | INVENTIVE |
| | | | | | | | | | | | FAIR | |
| 7 | 3 | 23 | 65 | 12 | VARIED | 16 | INCREASED | 3.0 × 10⁻⁴ | FAIR- | 6.0 × 10⁻¹ | VERY | COM- |
| | | | | | | | | | POOR | | POOR | PARATIVE |
| 8 | 4 | 27 | 70 | 3 | VARIED | 5 | INCREASED | 6.0 × 10⁻⁴ | FAIR- | 8.0 × 10⁻¹ | VERY | COM- |
| | | | | | | | | | POOR | | POOR | PARATIVE |
| 9 | 5 | 26 | 59 | 15 | VARIED | 13 | INCREASED | 7.0 × 10⁻⁴ | FAIR | 9.0 × 10⁻² | VERY | COM- |
| | | | | | | | | | | | POOR | PARATIVE |
| 10 | 15 | 28 | 57 | 15 | VARIED | 9 | INCREASED | 6.0 × 10⁻⁴ | FAIR- | 1.0 × 10⁻¹ | VERY | COM- |
| | | | | | | | | | POOR | | POOR | PARATIVE |
| 11 | 6 | 30 | 59 | 11 | VARIED | 25 | INCREASED | 2.0 × 10⁻⁴ | GOOD | 4.0 × 10⁻⁴ | GOOD- | INVENTIVE |
| | | | | | | | | | | | FAIR | |
| 12 | 7 | 27 | 56 | 17 | VARIED | 26 | INCREASED | 3.0 × 10⁻⁴ | GOOD | 6.0 × 10⁻⁴ | GOOD- | INVENTIVE |
| | | | | | | | | | | | FAIR | |
| 13 | 8 | 26 | 65 | 9 | VARIED | 23 | INCREASED | 4.0 × 10⁻⁴ | GOOD- | 9.0 × 10⁻³ | FAIR | INVENTIVE |
| | | | | | | | | | FAIR | | | |
| 14 | 9 | 27 | 61 | 12 | VARIED | 37 | INCREASED | 9.0 × 10⁻⁵ | GOOD | 2.0 × 10⁻⁴ | GOOD- | INVENTIVE |
| | | | | | | | | | | | FAIR | |
| 15 | 10 | 26 | 59 | 15 | VARIED | 35 | INCREASED | 8.0 × 10⁻⁵ | GOOD | 1.0 × 10⁻⁴ | GOOD- | INVENTIVE |
| | | | | | | | | | | | FAIR | |
| 16 | 11 | 27 | 58 | 15 | VARIED | 35 | INCREASED | 7.5 × 10⁻⁵ | GOOD | 9.5 × 10⁻⁵ | GOOD | INVENTIVE |
| 17 | 12 | 28 | 56 | 16 | VARIED | 38 | INCREASED | 8.0 × 10⁻⁵ | GOOD | 9.0 × 10⁻⁵ | GOOD- | INVENTIVE |
| | | | | | | | | | | | FAIR | |
| 18 | 13 | 24 | 63 | 13 | VARIED | 32 | INCREASED | 8.0 × 10⁻⁵ | GOOD | 9.0 × 10⁻⁵ | GOOD- | INVENTIVE |
| | | | | | | | | | | | FAIR | |
| 19 | 2 | 25 | 65 | 10 | VARIED | 21 | INCREASED | 2.0 × 10⁻⁴ | GOOD | 7.0 × 10⁻³ | FAIR | INVENTIVE |
| 20 | 2 | 26 | 53 | 21 | VARIED | 48 | INCREASED | 4.0 × 10⁻⁴ | GOOD | 1.0 × 10⁻² | FAIR | INVENTIVE |
| 21 | 10 | 26 | 59 | 15 | VARIED | 26 | INCREASED | 1.0 × 10⁻⁴ | GOOD | 5.0 × 10⁻³ | GOOD | INVENTIVE |
| 22 | 10 | 26 | 59 | 15 | VARIED | 42 | INCREASED | 9.0 × 10⁻⁵ | GOOD | 5.0 × 10⁻⁴ | GOOD | INVENTIVE |
| 23 | 12 | 28 | 56 | 16 | VARIED | 38 | INCREASED | 5.0 × 10⁻⁵ | GOOD | 7.0 × 10⁻⁵ | GOOD | INVENTIVE |
| 24 | 12 | 28 | 56 | 16 | VARIED | 38 | INCREASED | 2.0 × 10⁻⁵ | GOOD | 2.5 × 10⁻⁵ | GOOD | INVENTIVE |
| 25 | 12 | 28 | 56 | 16 | VARIED | 38 | INCREASED | 6.0 × 10⁻⁵ | GOOD | 6.0 × 10⁻⁴ | GOOD | INVENTIVE |
| 26 | 12 | 28 | 56 | 16 | VARIED | 38 | INCREASED | 7.0 × 10⁻⁶ | GOOD | 7.5 × 10⁻⁶ | GOOD | INVENTIVE |
| 27 | 12 | 28 | 56 | 16 | VARIED | 38 | INCREASED | 6.0 × 10⁻⁶ | GOOD | 6.5 × 10⁻⁶ | GOOD | INVENTIVE |
| 28 | 14 | 29 | 57 | 14 | VARIED | 40 | INCREASED | 5.0 × 10⁻⁶ | GOOD | 5.0 × 10⁻⁶ | GOOD | INVENTIVE |

*A: AVERAGE AT % ACROSS GAS BARRIER LAYER
*B: MAXIMUM AT %

The results in Table 2 indicate that a gas barrier film having a configuration according to the present invention has superior gas barrier properties (water vapor barrier characteristics) and adhesion compared to Comparative Examples. Such a gas barrier film still had superior gas barrier properties and adhesion after being stored in an environment at a high temperature and a high humidity and then being bended. Furthermore, a gas barrier layer formed on the gas barrier film had no crack and was not peeled off. These facts indicate that the gas barrier film has high durability.

### Example 2

### Fabrication of Organic EL Element

The gas barrier films fabricated in Example 1 were used to fabricate organic EL elements 1 to 28 as an example of electronic devices.

[Fabrication of Organic EL Element 1]

(Formation of First Electrode Layer)

A 150-nm thick ITO (indium tin oxide) film was formed on the gas barrier layer of the gas barrier film 1 fabricated in Example 1 through sputtering, and was patterned through photolithography, to form a first electrode layer. The film was patterned into a light-emitting area of 50 mm².

(Formation of Hole Transporting Layer)

A coating solution for a hole transporting layer, which is described below, was applied onto the first electrode layer formed on the gas barrier film 1 with an extrusion coater in an environment at 25° C. and 50% RH, and then dried and heated under the following conditions to form a hole transporting layer. The coating solution for a hole transporting layer was applied into a dry thickness of 50 nm.

Before application of the coating solution for a hole transporting layer, the surfaces of the gas barrier film 1 was cleaned and modified with light having an irradiation intensity of 15 mW/cm² radiating from a low-pressure mercury lamp generating light having a wavelength of 184.9 nm at a distance of 10 mm. The charge was neutralized with a neutralizer using weak X rays.

<Preparation of Coating Solution for Hole Transporting Layer>

Polyethylenedioxythiophene polystyrenesulfonate (PEDOT/PSS) (Bytron P AI 4083 manufactured by Bayer AG) was diluted into 65% with pure water and then into 5% with methanol, to prepare a coating solution for a hole transporting layer.

<Drying and Heating Conditions>

After the coating solution for a hole transporting layer was applied, the solvent was removed in a hot air stream at 100° C. applied toward the film surface at a discharge rate of 1 m/s and a flow rate distribution of 5% across the width from a height of 100 mm, and the film was heated at 150° C. from the back of the substrate with a heating device, to form a hole transporting layer.

(Formation of Light Emitting Layer)

A coating solution for a white-light emitting layer, which is described below, was applied with an extrusion coater onto the hole transporting layer under the following conditions, and then dried and heated to form a light emitting layer under the following conditions. The coating solution for a white-light emitting layer was applied into a dry thickness of 40 nm.

<Preparation of Coating Solution for White-Light Emitting Layer>

A host material composed of 1.0 g of the compound H-A as below, a first dopant composed of 100 mg of the compound D-A as below, a second dopant composed of 0.2 mg of the compound D-B as below, and a third dopant composed of 0.2 mg of the compound D-C as below were dissolved in 100 g of toluene to prepare a coating solution for a white-light emitting layer.

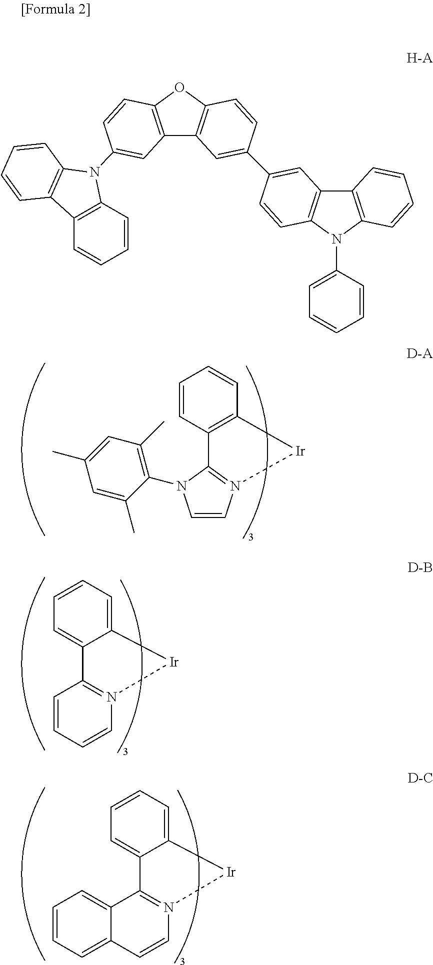

<Application Conditions>

The coating solution, heated to 25° C., was applied in an atmosphere having a nitrogen gas concentration of 99% or more at an application rate of 1 m/min.

<Drying and Heating Conditions>

After the coating solution for a white-light emitting layer was applied on the hole transporting layer, the solvent was removed in a hot air stream at 60° C. applied toward the film surface at a discharge rate of 1 m/s and a flow rate distribution of 5% across the width from a height of 100 mm, and the film was subsequently heated at 130° C. to form a light emitting layer.

(Formation of Electron Transporting Layer)

A coating solution for an electron transporting layer, which is described below, was applied onto the light emitting layer with an extrusion coater under the following conditions, and then dried and heated under the following conditions to form an electron transporting layer. The coating solution for an electron transporting layer was applied into a dry thickness of 30 nm.

<Preparation of Coating Solution for Electron Transporting Layer>

Compound E-A (described below) was dissolved in 2,2,3,3-tetrafluoro-1-propanol to prepare a 0.5 mass % solution as a coating solution for an electron transporting layer.

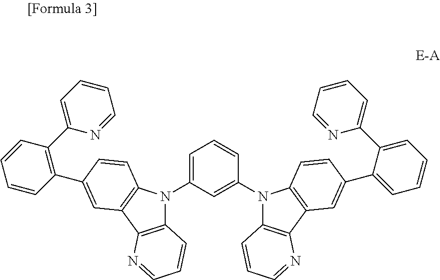 [SMILES: c1ccc(-c2ccccc2-c2ccc3c(c2)c2ncccc2n3-c2cccc(-n3c4ccc(-c5ccccc5-c5ccccn5)cc4c4ncccc43)c2)nc1]

<Application Conditions>

The coating solution for an electron transporting layer, heated to 25° C., was applied in an atmosphere having a nitrogen gas concentration of 99% or more at an application rate of 1 m/min.

<Drying and Heating Conditions>

After the coating solution for an electron transporting layer was applied on the light emitting layer, the solvent was removed in a hot air stream at 60° C. applied toward the film surface at a discharge rate of 1 m/s and a flow rate distribution of 5% across the width from a height of 100 mm, and the film was subsequently heated with a heating unit at 200° C. to form an electron transporting layer.

(Formation of Electron Injecting Layer)

An electron injecting layer was formed on the electron transporting layer in accordance with the following process.

The gas barrier film 1 including the electron transporting layer was placed in a decompression chamber, which was evacuated to 5×10⁻⁴ Pa. Cesium fluoride, which was provided on a tantalum deposition boat placed in the decompression chamber in advance, was heated to form an electron injecting layer having a thickness of 3 nm.

(Formation of Second Electrode)

A second electrode material composed of aluminum was vapor deposited under a vacuum of 5×10⁻⁴ Pa on the electron injecting layer, excepting the area that a lead of the first electrode is formed, through a mask pattern having a light-emitting area of 50 mm², to form a 100-nm thick second electrode layer having a lead.

(Cutting)

The laminate including the second electrode layer were again placed in a nitrogen atmosphere and cut into a predetermined size with an ultraviolet laser to fabricate an organic EL element 1.

(Electrode Lead Connection)

The resulting organic EL element 1 was connected to a flexible printed circuit board (base film composed of polyimide (12.5 μm) and rolled copper foil (18 μm), and a coverlay composed of polyimide (12.5 μm) having a surface plated with NiAu) via an anisotropically conductive film DP3232S9 manufactured by Sony Chemical & Information Device Corporation.

Pressure bonding conditions: Pressure bonding was carried out at 170° C. (ACF temperature of 140° C. measured with a separate thermocouple), under a pressure of 2 MPa for 10 seconds.

(Sealing)

The sealing member used was composed of a laminate (with a 1.5-μm thick adhesive layer) of 30-μm thick aluminum foil (manufactured by Toyo Aluminium K.K.) and a 12-μm thick poly(ethylene terephthalate) (PET) film bonded together with a dry lamination adhesive (two-component reactive urethane adhesive).

A thermo-curable adhesive agent was uniformly applied onto the aluminum foil surface (shiny surface) of the sealing member with a dispenser into an adhesive layer with a thickness of 20 μm.

The thermo-curable adhesive agent used in this case was a mixture of the epoxy-based adhesive agents (A) to (C) described below:

(A) Bisphenol A diglycidyl ether (DGEBA)

### (B) Dicyandiamide (DICY)

(C) Epoxy adduct curing accelerator

The sealing member was placed to cover a junction between the electrode to be extracted and the electrode lead, and tightly sealed with a pressing roller at temperature of 120° C., a pressure of 0.5 MPa, and a roller rate of 0.3 m/min.

[Fabrication of Organic EL Elements 2 to 28]

Organic EL elements 2 to 28 were fabricated as in the organic EL element 1, except that the gas barrier film 1 was replaced with the gas barrier films 2 to 28 fabricated in Example 1, respectively.

<<Evaluation of Organic EL Elements>>

The resulting organic EL elements 1 to 28 were evaluated for durability in accordance with the following procedures.

[Evaluation of Durability]

(Accelerated Deteriorating Treatment)

The organic EL elements were subjected to accelerated deteriorating treatment in an environment at 60° C. and 90% RH for 400 hours and then evaluated for black spots together with an organic EL element that was not subjected to accelerated deteriorating treatment.

(Measurement of Black Spots and Evaluation of Durability)

An electric current of 1 mA/cm² was applied to the organic EL elements after the accelerated deteriorating treatment and the organic EL element before the accelerated deteriorating treatment (blank sample) to emit light continuously for 24 hours. Partially magnified images of panels were captured with a 100 times microscope (MS-804 equipped with an MP-ZE25-200 lens manufactured by Moritex Corporation). The captured image was cut into 2 mm² squares to determine the ratio of the area of the black spots, and the rate of deteriorating resistance of the elements were calculated in accordance with the following expression.

The durability was evaluated in accordance with the following criteria based on the rate of deteriorating resistance of the elements. The elements ranked Excellent and Good have favorable characteristic in practical use.

Rate of deteriorating resistance of element (%)=(Area of black spots in element before accelerated deteriorating treatment)/(Area of black spots in element after accelerated deteriorating treatment)×100

EXCELLENT: Rate of deteriorating resistance of element is more than 90%
GOOD: Rate of deteriorating resistance of element is 75% or more and less than 90%
FAIR: Rate of deteriorating resistance of element is 60% or more and less than 75%
FAIR-POOR: Rate of deteriorating resistance of element is 45% or more and less than 60%
POOR: Rate of deteriorating resistance of element is less than 45%

The results determined in this way are listed in Table 3.

TABLE 3

| ORGANIC | EVALUATION OF | |
|---|---|---|
| EL ELEMENT | DURABILITY | REMARKS |
| 1 | POOR | COMPARATIVE |
| 2 | POOR | COMPARATIVE |
| 3 | FAIR-POOR | COMPARATIVE |
| 4 | POOR | COMPARATIVE |
| 5 | FAIR-POOR | COMPARATIVE |
| 6 | GOOD | INVENTIVE |
| 7 | POOR | COMPARATIVE |
| 8 | POOR | COMPARATIVE |
| 9 | POOR | COMPARATIVE |
| 10 | POOR | COMPARATIVE |
| 11 | GOOD | INVENTIVE |
| 12 | GOOD | INVENTIVE |
| 13 | GOOD | INVENTIVE |
| 14 | GOOD | INVENTIVE |
| 15 | GOOD | INVENTIVE |
| 16 | EXCELLENT | INVENTIVE |
| 17 | EXCELLENT | INVENTIVE |
| 18 | EXCELLENT | INVENTIVE |
| 19 | FAIR | INVENTIVE |
| 20 | FAIR | INVENTIVE |
| 21 | GOOD | INVENTIVE |
| 22 | GOOD | INVENTIVE |
| 23 | EXCELLENT | INVENTIVE |
| 24 | EXCELLENT | INVENTIVE |
| 25 | EXCELLENT | INVENTIVE |
| 26 | EXCELLENT | INVENTIVE |
| 27 | EXCELLENT | INVENTIVE |
| 28 | EXCELLENT | INVENTIVE |

The results in Table 3 indicates that the organic EL elements including each gas barrier film of the present invention have excellent durability since the rate of deteriorating resistance of such elements was 60% or more, whereas the rate of deteriorating resistance of elements including a gas barrier film in Comparative Examples was less than 60%.

The gas barrier films in the embodiment of the present invention thus have outstandingly high gas barrier properties and can be used as a sealing film for electronic devices such as organic EL devices.

### INDUSTRIAL APPLICABILITY

The method for producing the gas barrier film of the present invention can produce a gas barrier film having high gas barrier properties required for electronic devices used in environments at high temperature and high humidity, such as outdoor use, and also having excellent flexibility (high flexure resistance) and adhesion. Such a gas barrier film can be suitably used as a sealing member for electronic devices, such as organic electroluminescence panels, organic electroluminescence elements, organic photoelectric conversion elements, and liquid crystal displays.

### REFERENCE NUMERAL LIST

1 gas barrier film
2 resin substrate
2 stress absorbing layer
3 conductive layer
4 gas barrier layer
5 second gas barrier layer
6 transparent electrode
7 organic EL element (electronic device body)
8 adhesive layer
9 facing film
P organic EL element (electronic device)
11 feeding roller
21, 22, 23, 24 conveying rollers
31, 32 deposition rollers
41 gas supply pipe
51 power source to generate plasma
61, 62 magnetic field generators
71 take-up roller
A carbon distribution curve
B silicon distribution curve
C oxygen distribution curve
D oxygen-carbon distribution curve

1. A method for producing a gas barrier film including a gas barrier layer containing carbon atoms, silicon atoms, and oxygen atoms on a first surface of a resin substrate, and a conductive layer on a second surface of the resin substrate opposite of the first surface of the resin surface on which the gas barrier layer is formed, the method comprising:
forming the gas barrier layer on the first surface of the resin substrate with an oxygen gas and a material gas containing an organosilicon compound by plasma enhanced chemical vapor deposition in a discharge space of an applied magnetic field between rollers; and
forming the conductive layer on the second surface of the resin substrate opposite of the first surface of the resin substrate on which the gas barrier layer is formed, the conductive layer having a specific surface resistivity ranging from 1×10³ to 1×10¹⁰ Ω/sq in an environment of 23° C. and 50% RH.

2. The method for producing a gas barrier film according to claim 1, wherein the gas barrier layer is formed under the conditions satisfying all of following Items (1) to (4):
(1) the atomic percentage of carbon in the gas barrier layer continuously varies depending on a distance from the surface in a thickness direction within a region from a surface of the gas barrier layer to a distance of 89% of the thickness;
(2) the maximum value of the atomic percentage of carbon in the gas barrier layer is less than 20 at % in the thickness direction within the region from the surface of the gas barrier layer to a distance of 89% of the thickness;
(3) the atomic percentage of carbon in the gas barrier layer continuously increases across the thickness within a region from a distance of 90% to 95% of the thickness from the surface of the gas barrier layer (within a region of 5% to 10% from the surface adjacent to the resin substrate); and
(4) the maximum value of the atomic percentage of carbon in the gas barrier layer is at least 20 at % in the thickness direction within the region from a distance of 90% to 95% of the thickness from the surface of the gas barrier layer (within the region from 5% to 10% from the surface adjacent to the resin substrate).

3. The method for producing a gas barrier film according to claim 1, wherein the conductive layer contains resin and metal oxide.

4. The method for producing a gas barrier film according to claim 1, wherein a polysilazane solution is applied on the gas barrier layer and dried to form a coated film, and the coated film is irradiated with vacuum ultraviolet light having a wavelength of 200 nm or less for modification to form a second gas barrier layer.

5. A gas barrier film comprising:
a gas barrier layer containing carbon atoms, silicon atoms, and oxygen atoms on a first surface of a resin substrate; and
a conductive layer on a second surface of the resin substrate opposite of the first surface of the resin substrate on which the gas barrier layer is formed,
wherein the gas barrier layer is formed on the first surface of the resin substrate with an oxygen gas and a material gas containing an organosilicon compound by plasma enhanced chemical vapor deposition in a discharge space of an applied magnetic field between rollers, and the conductive layer is formed on the second surface of the resin substrate opposite of the first surface of the resin substrate on which the gas barrier is formed, the conductive layer having a specific surface resistivity ranging from 1×10³ to 1×10¹⁰ Ω/sq in an environment of 23° C. and 50% RH.

6. A gas barrier film according to claim 5, wherein the gas barrier film satisfies all of following Items (1) to (4):
(1) the atomic percentage of carbon in the gas barrier layer continuously varies depending on a distance from the surface in a thickness direction within a region from a surface of the gas barrier layer to a distance of 89% of the thickness;
(2) the maximum value of the atomic percentage of carbon in the gas barrier layer is less than 20 at % in the thickness direction within the region from the surface of the gas barrier layer to a distance of 89% of the thickness;
(3) the atomic percentage of carbon in the gas barrier layer continuously increases across the thickness within a region from a distance of 90% to 95% of the thickness from the surface of the gas barrier layer (within a region of 5% to 10% from the surface adjacent to the resin substrate); and
(4) the maximum value of the atomic percentage of carbon in the gas barrier layer is at least 20 at % in the thickness direction within the region from a distance of 90% to 95% of the thickness from the surface of the gas barrier layer (within the region from 5% to 10% from the surface adjacent to the resin substrate).

7. An electronic device comprising the gas barrier film 1 according to claim 5.
